(19) United States
(12) Patent Application Publication
(10) Pub. No.: US 2022/0336251 A1
(43) Pub. Date: Oct. 20, 2022

(54) Differential-Movement Transfer Stamps and Uses for Such Differential-Movement Transfer Stamps

(71) Applicant: VERLASE TECHNOLOGIES LLC, Bridgewater, NJ (US)

(72) Inventor: Ajaykumar R. Jain, Reno, NV (US)

(21) Appl. No.: 17/760,975

(22) PCT Filed: Aug. 4, 2020
(86) PCT No.: PCT/US20/44814

§ 371 Date: Mar. 16, 2022

Related U.S. Application Data
(60) Provisional application No. 63/100,406, filed on Mar. 12, 2020.
(60) Provisional application No. 62/974,445, filed on Dec. 10, 2019.
(60) Provisional application No. 62/973,739, filed on Oct. 23, 2019.
(60) Provisional application No. 62/973,346, filed on Sep. 30, 2019.
(60) Provisional application No. 62/973,063, filed on Sep. 16, 2019.

(51) Int. Cl. H01L 21/683; H01L 21/78

(52) U.S. Cl. CPC H01L 21/6835; H01L 21/7806

(57) ABSTRACT

Differential-movement transfer stamps for holding microelectronics substrates and/or one or more microelectronic-device dies. Each differential-movement transfer stamp is configured to temporarily securely hold corresponding respective microelectronics substrates for handling and/or during die portioning and/or to temporarily securely hold microelectronic-device dies, for example, for efficient mass transfer and precision placement of the microelectronic-device dies. In some embodiments, each differential-movement transfer stamp includes a plurality of functional units that each comprise or are otherwise associated with one or more dimension-changing components that are used for temporarily securing a microelectronics substrate to the differential-movement transfer stamp and/or for releasing the microelectronics substrate or microelectronic-device dies from the differential-movement transfer stamp. Various uses of the disclosed differential-movement transfer stamps, such as semiconductor processing and mass transfer for making electronic devices such as microLED displays, sensor arrays, and detector arrays, are also described.

### RELATED APPLICATION DATA

This application claims the benefit of priority of U.S. Provisional Patent Applications Ser. No. 62/973,063, filed on Sep. 16, 2019, Ser. No. 62/973,346, filed on Sep. 30, 2019, Ser. No. 62/973,739, filed on Oct. 23, 2019, Ser. No. 62/974,445, filed on Dec. 10, 2019, Ser. No. 63/100,406, filed on Mar. 12, 2020 and titled “Novel Transfer Stamp.” Each of these applications is incorporated by reference herein in its entirety.

### FIELD OF THE INVENTION

The present invention generally relates to the field of transfer stamps that are used to hold semiconductor dies and semiconductor substrates. In particular, the present invention is directed to differential-movement transfer stamps and uses for such differential-movement transfer stamps.

### BACKGROUND

Today's incumbent organic light-emitting diode (OLED) microdisplays have many shortcomings relative to AR (augmented reality) requirements in terms of color quality, resolution, brightness, efficiency, and longevity. Inorganic III-V nitride (GaN/InGaN/AlGaN) based microLEDs having individually addressable (red-green-blue) RGB pixels, would be hugely preferred for higher brightness (e.g., for daylight viewing), for high efficiency for long battery life and untethered use and for very compact forms, but unfortunately such microLEDs only emit monochrome (blue/violet) light. To realize high definition, full color, RGB pixels, the respective pixel and sub-pixel sizes for such inorganic LED (ILED) microdisplays can be on the order of sub 20 microns, or sub 10 microns, or even sub 5 microns. There is currently no mass transfer technology that can allow for the manufacturing of such microdisplays from highly optimized, pre-made, inorganic LED micro dies.

### SUMMARY OF THE DISCLOSURE

In one implementation, the present disclosure is directed to a tool for making an electronic device that includes a microelectronics-device die. The tool includes a differential-movement transfer stamp that includes: a working face designed and configured to removably secure the microelectronic-device die to the differential-movement transfer stamp; a first component having a first face exposed on the working face and comprising a first material; and a second component having a second face exposed on the working face and comprising a second material different from the first material; wherein: the first and second materials are selected so that, when at least one of the first and second materials is activated by at least one selected activator, the first and second faces experience a differential movement relative to one another in a direction normal to the working face; and when the microelectronic-device die is removably secured on the working face so as to extend over the first and second faces, the differential movement causes the differential-movement transfer stamp to release the microelectronic-device die.

In another implementation, the present disclosure is directed to a method of making a differential-movement transfer stamp having a working face designed and configured to removably secure and controllably release at least one microelectronic-device structure. The method includes fabricating at least one first component of a first material, the first component having a first face on the working face; and fabricating at least one second component of a second material, the second component having a second face on the working face; wherein at least one of the first and second materials comprises a dimension-changing material responsive to at least one selected activator and that, when activated, provides a differential movement between the first and second components that causes the differential-movement transfer stamp to controllably release the microelectronic-device structure removably secured to the differential-movement transfer stamp.

In yet another implementation, the present disclosure is directed to a method of manufacturing an electronic device. The method includes providing a receiving support; removably securing a microelectronic-device die to a working face of a differential-movement transfer stamp so that the microelectronic-device die at least partially extends over a first component and a second component; aligning the microelectronic-device die with a target die-receiving region on the receiving support; positioning the differential-movement transfer stamp and the receiving support relative to one another so that the microelectronic-device die is located at the target die-receiving region; and releasing the microelectronic-device die from the differential-movement transfer stamp, wherein the releasing includes activating at least one dimension-changing material that is part of at least one of the first and second components so as to cause a differential movement between the first and second components in a direction normal to the working face of the differential-movement transfer stamp, the differential movement causing the differential-movement transfer stamp to release the microelectronic-device from the working face.

In still another implementation, the present disclosure is directed to a method of processing a microelectronics substrate. The method includes removably securing the microelectronics substrate to the working face of a differential-movement transfer stamp that comprises: a first component having a first face exposed on the working face and comprising a first material; and a second component having a second face exposed on the working face and comprising a second material different from the first material; wherein: the first and second materials are selected so that, when at least one of the first and second materials is activated by a selected activator, the first and second faces experience a differential movement relative to one another in a direction normal to the working face so as to cause the differential-movement transfer stamp to release the microelectronics substrate or a plurality of microelectronic-device dies formed therefrom; and while the microelectronics substrate is removably secured to the differential-movement transfer stamp, processing the microelectronics substrate; and after processing the microelectronics substrate, activating at least one of the first and second materials so as to cause the differential movement that releases the microelectronics substrate or the plurality of microelectronic-device dies from the differential-movement transfer stamp.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a cross-sectional view of an example differential-movement transfer stamp made in accordance with aspects of the present invention;

FIG. 2 is a flow diagram of an example method of fabricating the differential-movement transfer stamp of FIG. 1;

FIGS. 3A to 3G are cross-sectional views illustrating various blocks of the example method of FIG. 2;

FIG. 4 is a flow diagram of another example method of fabricating a version of the differential-movement transfer stamp of FIG. 1;

FIGS. 5A to 5C are cross-sectional views illustrating various blocks of the example method of FIG. 4;

FIG. 6 is a flow diagram of a further example method of fabricating another version of the differential-movement transfer stamp of FIG. 1;

FIGS. 7A to 7G are cross-sectional views illustrating various blocks of the example method of FIG. 6;

FIGS. 8A to 8C are cross-sectional views of the differential-movement transfer stamp of FIG. 3G, illustrating example differing heights of the first and second components of the differential-movement transfer stamp;

FIG. 9 is a cross-sectional view of the differential-movement transfer stamp of FIG. 5C, illustrating examples of in-plane and out-of-plane ones of the first components of the differential-movement transfer stamp;

FIGS. 10A to 10E are cross-sectional views illustrating example architectural variants of a differential-movement transfer stamp of the present disclosure;

FIGS. 10F and 10G are plan views of a portion of the differential-movement transfer stamp of FIG. 7G, illustrating example relationships between functional units of the differential-movement transfer stamp and die-receiving regions that receive individual microelectronic-device dies during use;

FIG. 11 is a partial cross-sectional view of the differential-movement transfer stamp of FIG. 1, illustrating an example single functional unit;

FIGS. 12A and 12B are cross-sectional views of a functional unit of a differential-movement transfer stamp, illustrating the removable securing of a microelectronic-device die with the functional unit;

FIGS. 13A and 13B are cross-sectional views of a functional unit of a differential-movement transfer stamp, illustrating the removable securing of a microelectronic-device die with the functional unit via differential pressure (e.g., vacuum);

FIGS. 14A and 14B are cross-sectional views of a functional unit of a differential-movement transfer stamp, illustrating the removable securing of a microelectronic-device die with the functional unit via adhesive bonding;

FIG. 15A is a cross-sectional view of a functional unit of a differential-movement transfer stamp, illustrating the removable securing of a microelectronic-device die with the functional unit via a magnetic layer;

FIG. 15B is a cross-sectional view of a functional unit of a differential-movement transfer stamp, illustrating the removable securing of a microelectronic-device die with the functional unit via an electret layer;

FIG. 15C is a cross-sectional view of a functional unit of a differential-movement transfer stamp, illustrating the removable securing of a microelectronic-device die with the functional unit via capillary force;

FIGS. 16A and 16B are cross-sectional views of a functional unit of a differential-movement transfer stamp, illustrating the release of a microelectronic-device die by contraction of the first component of the functional unit;

FIGS. 17A and 17B are cross-sectional views of a functional unit of a differential-movement transfer stamp, illustrating the release of a microelectronic-device die by expansion of the second component of the functional unit;

FIGS. 18A and 18B are cross-sectional views of a functional unit of a differential-movement transfer stamp, illustrating the release of a microelectronic-device die by expansion of the first component of the functional unit;

FIGS. 19A and 19B are cross-sectional views of a functional unit of a differential-movement transfer stamp, illustrating the release of a microelectronic-device die by contraction of the second component of the functional unit;

FIGS. 20A to 20C are cross-sectional views of differing versions of the functional unit of FIGS. 16A and 16B, illustrating differing types of activators for activating the dimension-changing materials of the differing versions;

FIG. 21 is a flow diagram of an example method of using a differential-movement transfer stamp of the present disclosure to pick up and transfer one or more microelectronic-device dies to a receiving support;

FIGS. 22A to 22G are cross-sectional views illustrating various aspects of the blocks of the example method of FIG. 21;

FIG. 23 is a flow diagram of another example method of using a differential-movement transfer stamp of the present disclosure to hold a microelectronics substrate at least while singulating at least one microelectronic-device die therefrom and releasing the microelectronic-device die(s) therefrom;

FIGS. 24A to 24C are cross-sectional views illustrating various aspects of the blocks of the example method of FIG. 23;

FIGS. 25A to 25C are cross-sectional views of example variants of the differential-movement transfer stamp of FIG. 1, illustrating examples in in-planeness and out-of-planeness of functional units of the variants;

FIG. 25D is a cross-sectional view of a scenario in which it is desired to place a microelectronic-device die onto a receiving support between microelectronic-device dies already present on the receiving support where a differential-movement transfer stamp having out-of-plane functional units, such as in the manner of FIG. 25B or 25C, may be useful;

FIG. 25E is a cross-sectional view of a scenario in which it is desired to place a microelectronic-device die onto a receiving support adjacent to one or more microelectronic-device dies already present on the receiving support where a differential-movement transfer stamp having out-of-plane functional units, such as in the manner of FIG. 25B or 25C, may be useful; and

FIG. 26 is a cross-sectional view of the assembly of the microelectronic substrate and backing support of FIG. 22A, illustrating an example construction of the microelectronic substrate.

### I. GENERAL OVERVIEW

### I.A Example Embodiments

The present disclosure reveals a variety of embodiments into which broad aspects of the present disclosure can be embodied.

One such embodiment includes a differential-movement transfer stamp for manufacturing an electronic device, such as a microLED display device, a detector device, and a sensor device, or any combination thereof, among others. In this embodiment, the differential-movement transfer stamp comprises a body having a working face that releasably receives and holds at least one microelectronic device die, and typically plurality of individual microelectronic-device dies, during use. At least one, and typically a plurality, of each of first and second components are formed in, or are otherwise provided to, the body and arranged in a predetermined arrangement on the working face of the body for releasably holding and controllably releasing the individual microelectronic-device die(s), for example, individually, in subsets, or in their entireties. The first and second components are made of corresponding first and second materials. At least one of the first and second components is configured to provide a holding force that holds the one or more individual microelectronic-device dies on the working face of the differential-movement transfer stamp. At least one of the first and second materials comprises at least one dimension-changing material that is responsive to at least one selected activator so as to change dimension in a manner that results in differential movement between surfaces of the first and second components on the working face of the differential-movement transfer stamp in a direction substantially normal to the working face. Examples of activatable shape-changing materials suitable for use in a differential-movement transfer stamp of the present disclosure are described below.

As illustrated in example discussed below, this differential movement allows for controlled release of the individual microelectronic-device die(s) when the individual microelectronic-device die(s) is/are removably secured to the differential-movement transfer stamp. For example, in some embodiments, differential outward movement (relative to the body of the differential-movement transfer stamp) of one of the first and second components relative to the other effectively pushes an individual microelectronic-device die off of the working face. As another example, in some embodiments, differential inward movement (relative to the body of the differential-movement transfer stamp) of one of the first and second components relative to the other pulls an individual microelectronic-device die against the other of the first and second component, which acts as a stop. As the inward movement continues, the stop holds the individual microelectronic-device die as the inwardly moving component disengages from the individual microelectronic-device die, thereby releasing it from the working face of the differential-movement transfer stamp. These and other differential-movement release mechanisms and scenarios are illustrated in detail below and in the accompanying figures.

Examples of selected activators for activating one or more dimension changing materials include, but are not limited to, electromagnetic radiation (e.g., visible light, ultraviolet light, infrared light, etc.), heat, voltage, electrical current, and combinations thereof, among others. Each selected activator may be applied using an activation system, which may be part of a differential-movement-transfer tool that also includes the differential-movement transfer stamp. An example activation system includes a scanning laser that can be controlled to activate the dimension-changing material(s) of the first and/or second components, for example, on an individual microelectronic-device die by individual microelectronic-device die basis. As another example, an activation system may include activation circuitry which may be in electrical communication with each of the controllable dimension-changing materials and be designed and configured to electrically communicate with the dimension-changing material to control release of the plurality of individual microelectronic-device dies from the differential-movement transfer stamp via differential movement between the first and second components as discussed above.

In some embodiments, at least one of the first and second components may be provided with a bonding agent that tends to hold an individual microelectronic die on the working face of the differential-movement transfer stamp. In embodiments in which the dimension-changing material dimensionally expands outwardly relative to the body of the differential-movement transfer stamp, such a bonding agent, if used, is typically provided to the one of the first and second components that does not expand dimensionally outward. In embodiments in which the dimension-changing material dimensionally contracts inwardly relative to the body of the differential-movement transfer stamp, such as bonding agent, if used, is typically provided to the one of the first and second components that dimensionally contracts inwardly. Examples of bonding agents suitable for use with a differential-movement transfer stamp of the present disclosure are provided below.

In some embodiments, at least one of the first and second components may be provided with an anti-bonding agent that tends to resist holding an individual microelectronic die on the working face of the differential-movement transfer stamp. In embodiments in which the dimension-changing material dimensionally expands outwardly relative to the body of the differential-movement transfer stamp, such an anti-bonding agent, if used, is typically provided to the one of the first and second components that expands dimensionally outward. In embodiments in which the dimension-changing material dimensionally contracts inwardly relative to the body of the differential-movement transfer stamp, such an anti-bonding agent, if used, is typically provided to the one of the first and second components that does not dimensionally contract inwardly. Examples of anti-bonding agents suitable for use with a differential-movement transfer stamp of the present disclosure are provided below.

A further revealed embodiment includes a method of making a differential-movement transfer stamp, such as the differential-movement transfer stamp described above for use in manufacturing an electronic device, such as, for example, a microLED display device, a detector device, a sensor device, or a combination thereof, among others. As those skilled in the art understand, the manufacturing of such devices typically utilizes a plurality of individual microelectronic-device dies arranged in a predetermined arrangement during at least one step of the manufacturing. Correspondingly, a method of making a differential-movement transfer stamp for such manufacturing may comprise using the predetermined arrangement of the plurality of individual microelectronic-device dies used during the device manufacturing to determine a pattern of a plurality of first and second components spatially arranged in the differential-movement transfer stamp. This allows the differential-movement transfer stamp to be customized to the manufacturing task at hand. In some embodiments, the pattern of the plurality of first and second components may replicate, on a location-by-location basis, the full density of microelectronic-device dies on the electronic device. In some embodiments, the pattern of the plurality of first and second components may replicate, on a location-by-location basis, a reduced density of microelectronic-device dies on the electronic device. For example, if the electronic device comprises an RGB display, the pattern of the first and second components of the differential-movement transfer stamp at issue may be designed for microLEDs of only one of the red, green, and blue colors. Assuming a 1:1:1 ratio of RGB microLEDs per pixel, the density of the pattern on such a differential movement transfer stamp will be one-third of the full density of the RGB display. As another example, if the electronic device includes both emitting elements and separate sensing elements interspersed among the emitting elements, the pattern of the first and second components of the differential-movement transfer stamp at issue may be designed for the sensing elements only, perhaps with another differential-movement transfer stamp designed for the emitting elements. Assuming an alternating arrangement of the emitting and sensing elements and that both elements have the same area, the density of the pattern on such a differential movement transfer stamp will be half of the full density of the finished electronic device. Those skilled in the art will understand that these examples are merely illustrative and nonlimiting.

The differential-movement transfer stamp includes a working face that confronts the plurality of individual microelectronic-device dies during use of the differential-movement transfer stamp. The plurality of first and second components are formed in or otherwise provided to the differential-movement transfer stamp in the pattern determined based on the end use of the differential-movement transfer stamp, with the pattern manifested on the working face. At least one the first and second component types is provided with at least one dimension-changing material that is activatable to change dimension by at least one selected activator. The at least one dimension-changing material may be used alone, in combination with a non-dimension-changing material, or in combination with another dimension-changing material. Each of the at least one dimension-changing material may be, for example, any of the dimension-changing materials disclosed herein or equivalent thereto.

In some embodiments, making a differential-movement transfer stamp of the present disclosure may include providing one or more bonding agents to at least one of the first and second components, for example, as discussed above relative to the example differential-movement transfer stamp itself. Also, in some embodiments, making a differential-movement transfer stamp of the present disclosure may include providing one or more anti-bonding agents to one of the first and second components, for example, as discussed above relative to the example differential-movement transfer stamp itself.

Yet another revealed embodiment includes a method of making an electronic device, such as a microLED display device, a detector device, a sensor device, or a combination thereof, among others. In an example, the method comprises providing individual microelectronic-device dies, wherein the individual microelectronic-device dies arranged in a predetermined arrangement and removably engaged with a support, such as a fabrication chuck, an intermediate substrate, or a temporary holder, among other things. A differential-movement transfer stamp is provided for transferring at least one of the individual microelectronic-device dies on the support from that support to a receiving support. The receiving support may be, for example, a backplane of an electronic device, an intermediate substrate, or another temporary holding support, among others

The differential-movement transfer stamp has a working face and includes first and second components arranged on the working face for receiving at least one individual microelectronic-device die. The first and second components are arranged in a pattern relating to the predetermined arrangement of the individual microelectronic-device dies when they are engaged with the support from which they will be moved using the differential-movement transfer stamp. The working face of the differential-movement transfer stamp and the individual microelectronic-device dies on the substrate are registered relative to one another so that the pattern of the first and second components on the differential-movement transfer stamp is located in a desired location relative to the arrangement of the individual microelectronic-device dies on the support. When the individual microelectronic-device dies and the first and second components are in proper registration with one another, the individual microelectronic-device dies and the working face of the differential-movement transfer stamp are contacted with one another so that the individual microelectronic-device dies become releasably secured to the working face of the differential-movement transfer stamp. The individual microelectronic-device dies are disengaged from the support. In some embodiments, the differential-movement transfer stamp, now releasably holding the individual microelectronic-device dies, may be moved proximate to a receiving support. Alternatively, the donating support may be moved away from the differential-movement transfer stamp and replaced with a receiving support. One or more dimension-changing materials within one, the other, or both, of the first and second components may be activate so as to cause a differential movement between the first and second components that releases at least one of the individual microelectronic-device dies from the differential-movement transfer stamp and transferred onto the receiving support at a desired location.

Another revealed embodiment includes a method of making an electronic device, such a microLED display device, a detector device, or a sensor device, among others. This method may include removably securing a microelectronics substrate to the working face of a differential-movement transfer stamp. In this example, the differential-movement transfer stamp includes a plurality of a first and second components formed in, or otherwise provided to, the working face of the differential-movement transfer stamp. The first and second components are spatially arranged in a predetermined arrangement and have associated therewith at least one dimension-changing material. The microelectronics substrate includes microelectronic devices spatially arranged relative to one another in concert with the predetermined arrangement of the first and second components of the differential-movement transfer stamp to allow the controlled release of individual ones, all, or one or more selected subsets of individual microelectronic device dies corresponding to the individual microelectronic devices after singulation. While the microelectronics substrate is removably secured to the differential-movement transfer stamp, the microelectronics substrate is partitioned to separate, or singulate, ones of the microelectronics devices from one another to create the individual microelectronic-device dies. After partitioning the microelectronics substrate, that at least one dimension-changing material is activated so that at least one of the individual microelectronic-device dies is released from the differential-movement transfer stamp and transferred onto a receiving support at a predetermined location.

Still another revealed embodiment includes a method of working a microelectronics substrate. The method comprises, among other things, removably securing the microelectronics substrate to a working face of a differential-movement transfer stamp, wherein the differential-movement transfer stamp first and second components, with at least one of the first and second components including at least one controllable dimension-changing material. While the microelectronics substrate is removably secured to the differential-movement transfer stamp, the microelectronics substrate is processed using any one or more suitable processing techniques, such as one or more semiconductor-wafer processing techniques. After processing the microelectronics substrate, the at least one controllable dimension-changing material is activated using one or more suitable selected activators so as to release the microelectronics substrate from the differential-movement transfer stamp.

These and other example embodiments are described below in detail and in the claims accompanying this disclosure upon the original filing of this disclosure. Those claims are incorporated into this detailed description section in their entireties.

### I.B Terminology and Drawing Convention

Following are definitions used herein and in the appended claims. These definitions are intended to assist the reader in understanding the scope of the present disclosure and the accompanying claims.

“Substrate”—any sort of body suitable for the intended purpose of the substrate. As a few non-limiting examples a substrate can be in the form of a microelectronics-type wafer, a sheet, or a block, among many other forms. As used herein, “substrate” does not necessarily connote that the body at issue function as a body, layer, etc., that underlies one or more layers or other structures, though is certainly can have that connotation in some uses herein.

“Microelectronics substrate”—any substrate, semiconductor or otherwise (such as a wafer), used for creating microelectronic devices and can also the structure(s) that results from processing to form microelectronics on the substrate when such structure(s) are present.

“Electronic device”—any electronic device, such as an electronic display, a sensor array, and a detector array, and any combination thereof, among others.

“Microelectronic device”—any individual electrical component, e.g., LED, laser diode, transistor, etc. or any collection of such components that make up an overall device, such as a microprocessor, memory, etc.

“Microelectronic-device die” and “individual microelectronic-device die”—the structure that contains a microelectronic device, typically formed by partitioning a microelectronic substrate into individual bodies that are separate and distinct from one another.

“Working face”—the face of the outermost layer of a differential-movement transfer stamp that confronts a microelectronics substrate or one or more plurality of individual microelectronic-device dies.

“Receiving support”—anything that receives one or more individual microelectronic-device dies when released from the differential-movement transfer stamp; can be, e.g., a backplane of an electronic device, an intermediate substrate, or a temporary holder, such as another transfer stamp of the present disclosure, among other things.

“Differential-movement transfer stamp”—a transfer stamp for transferring one or more individual microelectronic-device dies from a first location to a second location based on differential movement between first and second components of the stamp that results in release of the die(s) from the stamp.

“First component” and “second component”—parts of the differential-movement transfer stamp, at least one of which moves relative to the other during activation to create a differential in movement between the first and second components that causes the differential-movement transfer stamp to release one or more individual microelectronic-device dies from the stamp. In some embodiments, the first component may be a stop against which a die is forced by retraction of the second component. In some embodiments, the first component may be holder from which a die is released by expansion of the second component. In some embodiments, the roles of the first and second components may be reversed. For example, in the context of the preceding examples relative to the first component, the second component may be a stop against which a die is forced by retraction of the first component, and the second component may be holder from which a die is released by expansion of the first component. In some embodiments, the first and second components may be formed of separate and distinct structures and/or materials relative to one another, while in some embodiments the first and second components may be formed from the same structures and/or same materials as one another.

“Functional unit”—a combination of first and second components, or a portion(s) of one, the other, or both of the first and second components, that is the minimum structure necessary to perform the functions of releasably holding one of the bodies for which the differential-movement transfer stamp at issue is designed, such as a microelectronic-device die, a wafer, a substrate, etc., and releasing that body by differential movement of the first and second components.

“Dimension-changing material”—a material that controllably contracts or expands and can be used in either of the first and second components of the differential-movement transfer stamp. In some embodiments, one of the first and second components comprises an expanding material and the other comprises a contracting material. In the context of this disclosure, a material is a “dimension-changing material” because it is selected and/or used to exploit its dimension-changing property to effect the controlled release of a microelectronic-device die. Materials that are not selected and/or used for their dimension-changing ability are not “dimension-changing materials” under the present disclosure. For example, a material that undergoes incidental thermal expansion during use but does not cause a release because it was not designed to do so is not a dimension-changing material for the purposes of this disclosure.

The dimension change of a dimension-changing material may be characterized as either reversible or irreversible. A dimension change that is reversible experiences a functionally temporary change in dimension from an initial unactivated dimension to an activated dimension in response to activation and then substantially or entirely back to the initial unactivated dimension subsequent to activation. While some reversible dimension-changing materials may not fully recover their pre-activation dimensions following activation, these materials are deemed to be reversible when the relevant dimensions change in a direction toward their pre-activation dimensions to a point that the dimension-changing materials can be reused to perform their intended role in the differential-movement transfer process.

In contrast, dimension change that is irreversible experiences a functionally permanent change in dimension from an initial unactivated dimension to an activated dimension in response to activation. An irreversible dimension-changing material typically cannot be reused because the dimension change it underwent during activation is permanent and prevents the dimension-changing material from re-performing its design release function.

In some embodiments, a differential-movement transfer stamp (utilizing a reversibly dimension-changing material may be used multiple times without removing and replacing the dimension-changing material. In some embodiments, a differential-movement transfer stamp utilizing an irreversibly dimension-changing material may be reused by replacing the previously activated dimension-changing material.

“Activator”—anything that causes a dimension-changing material to make the desired dimension change, including light, heat, electricity, chemistry, etc.

“Bonding agent”—anything that causes a bond between any two separate and distinct structures, such as the first or second component of the differential-movement transfer stamp on the one hand and a microelectronic-device die on the other that allows the microelectronic device die to be removably secured to the differential-movement transfer stamp. A bonding agent can be, for example, an adhesive, a magnetic film, a vacuum chamber, an electrostatic layer, etc.

“Anti-bonding agent”—anything provided to any structure, such that the first or second component of the differential-movement transfer stamp or the walls of a cavity subsequently receiving another material, that prevents or inhibits bonding between that structure and another structure, such as a microelectronic-device die or a dimension-changing material. An anti-bonding agent can be, for example, an anti-stick coating, a repellant (that does not overcome the bond of the bonding agent), surface texturing, etc.

“Mean position”—When used in the context of a surface, for example, a working surface, or face, of a differential-movement transfer stamp, the mean position of the surface is used to define the location of a plane, curve, or other shape for a surface having high spots and low spots. In one example for a surface having multiple planar regions lying in differing parallel planes, the mean position of the surface may be determined by determining the location of a plane, parallel to the differing parallel planes, that represents the mean location of those parallel planes.

“Release axis”—The axis of a differential-movement transfer stamp that defines the direction that each microelectronic-device die is released from the differential-movement transfer stamp. For differential-movement transfer stamps having entirely planar working surfaces, the release axis is globally normal to the working surface across the entire working surface. For differential-movement transfer stamps having curved working surfaces, the release axis is locally normal to the working surface at the location of the particular microelectronic-device die being released. For differential-movement transfer stamps having multiple planar regions lying in differing parallel planes, the release axis is normal to the planar region under consideration.

“Target die-receiving region”—a region on a microelectronics substrate that receives a corresponding microelectronic-device die and is the final destination for the die in the finished electronic device.

Spatial terms, such as “up”, “down”, “upper”, “lower”, “top”, “bottom”, etc., as used herein are relative to the accompanying figures viewed in their correct orientation and should not be viewed as absolutes. For example, if an element of a particular figure is described as having an “upper face”, this does not dictate or imply that the identified face must be located on the vertically upward side of that element. Rather, that face may in practice be spatially located in any orientation in practice, such as downward, laterally sideways, skewed relative to vertical, etc. Similarly, locational terms, such as “front”, “back”, “frontside”, backside”, etc., as used herein for certain elements illustrated in the figures are arbitrary and not intended to necessarily relate to any particular functionality of the corresponding element. For example, when referring to the “front surface” of a microelectronic-device die that is an LED die, the “front surface” should not be construed as necessarily being the surface of the LED die from which light is emitted. While in some instances this may indeed be the case, in other cases it is not.

It is noted that throughout the accompanying drawings, when a plurality of a particular component is present, only one or fewer than all of such structures, components, etc., are actually labeled to avoid clutter. Those skilled in the art will understand that like-appearing structures, components, etc., are addressed in the detailed descriptions below despite not being labeled. It is also noted that the drawings are merely illustrative and that most real-world instantiations of a differential-movement transfer stamp made in accordance with the present disclosure will have many more functional units of first and second components than shown.

### II. Example Embodiments

Turning now to the drawings, FIG. 1 illustrates an example differential-movement transfer stamp 100 made in accordance with aspects of the present disclosure. In this example, the differential-movement transfer stamp 100 includes a substrate 104, a plurality of first components 108, and a plurality of second components 112. In this example, optional coating 116, examples of which are described below in detail, separates the plurality of first components 108 from corresponding ones of the plurality of second components 112. Also in this example, the differential-movement transfer stamp 100 is designed to releasably hold and release a plurality of microelectronic-device dies (not shown). Consequently, the first components 108 and the second components 112 are arranged so that the differential-movement transfer stamp 100 includes a plurality of functional units 120 (only one labeled) corresponding, respectively, to the plurality of microelectronic-device dies that the differential-movement transfer stamp is designed to engage. As discussed in detail below, either the first components 108 or the second components 112, or even in some cases both the first and second components, can include at least one dimension-changing material that effects the differential movement that provides the release functionality.

For example, FIG. 1 may illustrate the differential-movement transfer stamp 100 prior to the dimension-changing material(s) being activated. In this case, the plurality of microelectronic-device dies would be releasable secured to the upper (relative to FIG. 1) ends of the first components 108. To effect release, for example, the second components 112 may be non-dimension-changing and the first components 108 may be made of at least one dimension-changing material that contracts when activated so that the first components effectively retract, so that their upper ends move below the upper ends of the second components 112 such that the second components effectively pull the first components off of the microelectronic-device dies so as to release the microelectronic device-dies from the differential-movement transfer stamp 100. As another example, the first components 108 may be non-dimension-changing and the second components 112 may be made of at least one dimension-changing material that expands when activated, so that the second components effectively extend so that their upper ends move above the upper ends of the first components 108 such that the second components effectively push the microelectronic-device dies off of the first components so as to release the microelectronic-device dies from the differential-movement transfer stamp 100. In yet another example, the first components 108 may be made of at least one contracting material, and the second components 112 may be made of at least one expanding material. In a further example, the first components 108 and the second components 112 may be made of differing expanding dimension-changing materials having differing expansion responses so that there ends up being releasing differential movement between the first and second components. Conversely, but similarly, the first components 108 and the second components 112 may be made of differing contracting dimension-changing materials.

One or both of the first and second components 108, 112 can be manufactured in-situ during the construction of the differential-movement transfer stamp 100, or alternatively, one or both of the first and second components can be built ex-situ, and then, during the construction of the differential-movement transfer stamp, it/they can be incorporated into the functional unit(s) 120 of the differential-movement transfer stamp as suitable.

In some embodiments, one or more optional agents 124 may be used on each of the plurality of first component 108, and one or more optional agents 128 may be used on each of the plurality of second component 112. Such optional agents include bonding agents and anti-bonding agents, among others. As can be appreciated, one or more bonding agents may be applied to the relevant ones of the first and second components 108, 112 for initially releasably securing the microelectronic-device dies to the differential-movement transfer stamp 100. Similarly, one or more anti-bonding agents may be applied to the relevant ones of the first and second components 108, 112 for inhibiting bonding of the microelectronic-device dies to the others of the first and second components during the release phase of using the differential-movement transfer stamp 100. As an example in the context of FIG. 1 showing the differential-movement transfer stamp 100 in a state prior to activation, the optional coating(s) 124 on the first components 108 may be one or more bonding agents to effect the initial releasable securement, while the optional second coating(s) 128 on the second components 112 may be one or more anti-bonding agents to inhibit the microelectronic-device dies from bonding to the second components during the release phase of using the differential-movement transfer stamp 100.

It is noted that the combination of the substrate 104 and first component 108, and second component 112 without any additional treatment(s) applied thereto, may be considered as the differential-movement transfer stamp 100. The optional coating(s) 124 on the first component 108 and the optional coating(s) 128 on the second component 112 may be present as a particular design may require. Additional details on each of these elements and their functions, as well as examples of each of these elements, are described and provided below.

At a high level and as will become apparent from reading the entire disclosure, alternatively to using the differential-movement transfer stamp 100 for microelectronic-device dies, it may be used to removably secure a microelectronics substrate wafer (not shown) atop the working face 132 of the differential-movement transfer stamp structure, here the exposed top (relative to FIG. 1) surface of optional coating(s) 124, for further processing for a desired purpose. Example uses for the differential-movement transfer stamp 100 include, but are not limited to, removably securing a microelectronics substrate for further processing, removably securing a microelectronics substrate during in-situ individual microelectronic-device die creation in the microelectronics substrate, and removably securing the in-situ created individual microelectronic-device dies to allow for mass transfer of the individual microelectronic-device dies onto a separate receiving support or location on demand, and removably securing ex-situ created individual microelectronic-device dies to allow for mass transfer of the individual microelectronic-device dies onto a separate receiving support (not shown) or location on demand, among others.

The differential-movement transfer stamp 100 may be part of a tool 136 that includes other components, such as one or more activation systems 140 and one or more manipulation systems 144, among others. Each activation system 140 may be used to, or participate in, activation of the one or more dimension-changing materials present in the differential-movement transfer stamp 100. Examples of activation systems suitable for use as activation system(s) 140 include, but are not limited to, laser-based systems, electrical systems, and heating systems, among others. Each manipulation system 144 may be provided for manipulating, or participating in manipulating, the differential-movement transfer stamp 100, one or more receiving supports (not shown), such as microelectronics substrates and/or intermediate supports, and one or more microelectronic-device die sources, among others. Those skilled in the art of semiconductor fabrication will readily understand how to implement the activation system(s) 140 and/or the manipulation system(s) 144 suitable for the particular use of a differential-movement transfer stamp of the present disclosure, such as the differential-movement transfer stamp 100 of FIG. 1. Regarding electrical and/or thermal activation systems, individual addressability of individual functional units, such as functional units 120, can be achieved using passive matrix and active matrix addressing. Such addressing circuitry is very commonly used in electronic displays and televisions and is well known in the art. Such conventional circuitry could be adapted as required for this work.

The tool may further include a control system 146 that may comprise any suitable hardware or hardware+software combination that is able to interface with the activation system(s) 140 and/or manipulation system(s) 144 to achieve the desired activation and/or de-activation functionality and/or desired movement. Those skilled in the art will readily understand how the control system 146 can be configured for any particular application of the differential-movement transfer stamp 100. Depending on the needs of the application(s) for the differential-movement transfer stamp 100, the control systems 146 and/or activation system(s) 140 may be configured to address the activatable ones of the first and/or second component(s) 108, 112 individually, globally, by type, and/or in groupings containing fewer than all of any particular type of the components.

### II.A Substrate

Substrate 104 may be rigid or flexible and may be composed of one or more polymers, one or more ceramics, one or more metals, one or more papers, one or more fabrics, or one or more glasses, or any combination thereof, among other things. The substrate 104 may be transparent, opaque, or translucent, or any combination thereof. Each material of the substrate 104 may be a conductor, an insulator, or a semiconductor, or any combination thereof. Each material may be inorganic or organic or a combination thereof and may be single crystal, polycrystalline, oriented (or textured) polycrystalline, or amorphous in morphology.

Material for the substrate 104 may be porous or non-porous or a combination thereof. The pores (not shown), if present, in the substrate 104 may be created artificially or may exist naturally. The pores, if present, in the substrate 104 may be randomly located or deterministically placed. There are fundamentally no limits on the size and shape of the pores in the substrate 104.

There are fundamentally no limits on the thickness of the substrate 104, and in some embodiments the thickness may range from a few microns to several millimeters as desired by the application at issue. Additionally, other functionality/functional agent(s) (not shown) may be deposited in or on the surfaces of the substrate 104. The agent(s) may act as a gasket layer, flex/compliant layer, anti-stick/anti-abrasion layer, barrier layer, passivation layer, planarizing layer, adhesive layer, etc. These functional layers include, but are not limited to, organic or inorganic layers. While certain representative examples have been mentioned for purposes of illustrating the wide variety of substrates that can be used for the substrate 104, it will be apparent to those skilled in the art that substrates not disclosed herein may be made without departing from the scope of the invention.

### II.B Dimension-Changing Materials

Each of the one or more dimension-changing materials of the first and/or second components 108, 112 may comprise a reversible dimension-changing material, such as a shape memory polymer, a shape memory alloy, a liquid-crystal elastomer, a dielectric elastomer, a ferroelectric elastomer, or any combination thereof, among others. Alternatively, each of the one or more dimension-changing materials of the first and/or second components 108, 112 may comprise an irreversible dimension-changing material, such as a shape memory polymer, a heat shrink material, a cold shrink material, a light activated heat shrink material, a photoactivated material, a photoresist material, a light-curable adhesive, a light-curable epoxy, or any combination thereof, among others. Examples of particular dimension-changing materials are described below.

### II.B.1 Liquid-Crystal Elastomers

A liquid-crystal elastomer (LCE) as reversible dimension-changing material comprise one or more liquid-crystal elastomer materials. These liquid-crystal elastomer materials undergo a dimensional change (mechanical expansion/contraction) when an external stimulus, or activator, (such as light, heat, etc.) is applied. It is this dimensional change that is exploited in the present disclosure to mechanically create the differential movement in a differential-movement transfer stamp of the present disclosure, such as the differential-movement transfer stamp 100 of FIG. 1, that effects release.

There are no limits on the choice of materials used to make the liquid-crystal elastomer elements, nor are there any restrictions on the choice of construction techniques and architectures used. There are no constraints on the amount of dimensional change a liquid-crystal elastomer element may undergo, as long as it serves its intended purpose Some examples on material choices and deposition techniques are listed below.

Composition material for the liquid-crystal may include thermotropic or lyotropic liquid crystals. These may consist of, but not be limited to, any of the following phases, such as: nematic phase, biaxial nematic phase, smectic phase, and other smectic phases (˜26 polymorphs), twisted nematic or chiral phases, cholesteric, Blue phases, discotic phases, calamitic phases, conic phases, discontinuous cubic phase (micellar cubic phase), hexagonal phase (hexagonal columnar phase), lamellar phase, bicontinuous cubic phase, reverse hexagonal columnar phase, inverse cubic phase (Inverse micellar phase). The liquid crystal might further be composed of metallotropic liquid crystals, biological liquid crystals, mineral liquid crystals, polymeric liquid crystals, layered polymer cholesteric liquid crystal (pCLC), liquid crystal elastomers, cholesteric LC elastomers, polymer dispersed liquid crystals, etc.

Composition material for the elastomers may include thermosets or thermoplastics (TPE). Materials such as, but not limited to: natural rubber, natural polyisoprene, isoprene rubber, butadiene rubber, chloroprene rubber, neoprene, baypren, polychloroprene, etc. chlorinated polyethylene (CPE), chlorosulfonyl polyethylene (CSM), epichlorhydrin (CO/ECO), Ethylene propylene (EPM/EPDM), butyl rubber, halogenated butyl rubbers, bromobutyl (BIIR), chlorobutyl (CIIR), styrene butadiene rubber, nitrile rubber, hydrogenated nitrile rubbers, ethylene propylene rubber, Ethylene propylene diene rubber, epichlorohydrin rubber, polyacrylic rubber, Silicone rubber, PDMS, Acrylics, fluorosilicone, fluoroelastomers, polyether block amides, perfluoroelastomers, chlorosulfonated polyethylene, ethylene-vinyl acetate, fluorocarbon, isoprene (IR), perfluorocarbon (FFKM), polysulphide OT/EOT, polyurethane, tetrafluoroethylene propylene, thermoplastic urethane elastomers, styrenic block copolymers (SBS, SIS, SEBS), copolyether ester elastomers, polyester amide elastomers, polysulfide rubber, elastolefin fiber, resilin and elastin proteins, etc. may be utilized in the LCEs.

A wide variety of deposition methods exist to deposit liquid-crystal elastomeric elements, such as the first and/or second components 108, 112. Cited below are a few deposition techniques that may be used, but not limited to: spin-coating process, spray-coating process, Langmuir-Blodgett process, sol gel, roll-on coating process; printing processes; transfer processes; ink-jet processes; and powder-jet processes, etc. may also be utilized. There are fundamentally no limits on the thickness of these coating layers. They may be as thin as a few hundred nanometers to several tens of microns thick or more.

Two or more of the liquid-crystal elastomeric materials may be combined and deposited together. These two or more materials may be actuated by the same or different stimulus. While certain representative embodiments have been shown for purposes of illustrating the wide variety coating materials that may be used, it will be apparent to those skilled in the art that other coating materials not disclosed herein may be used without departing from the scope of the invention.

### II.B.2 Dielectric Elastomers

A dielectric elastomer as reversible dimension-changing material may comprise one or more dielectric elastomer materials. These dielectric elastomer materials undergo a dimensional change (mechanical contraction; compressing in thickness) when an electric voltage (activator) is applied over a thin dielectric elastomeric layer sandwiched between two compliant electrodes. It is this dimensional change that is exploited in the present disclosure to mechanically create the differential movement in a differential-movement transfer stamp of the present disclosure, such as the differential-movement transfer stamp 100 of FIG. 1, that effects release.

There are no limits on the choice of materials used to make the dielectric elastomer elements, nor are there any restrictions on the choice of construction techniques and architectures used. There are no constraints on the amount of dimensional change a dielectric elastomer element may undergo, as long as it serves its intended purpose. Some examples of material choices and deposition techniques are listed below.

Dielectric elastomers are also known variously as electroactive polymers (EAPs). Typical composition materials for dielectric elastomers may be acrylic, silicone, and other elastomers. The elastomeric material might be made porous (e.g., entrapped with air) if so desired. For example (but not limited to), the elastomeric matrix may be perforated using aerogel, xerogel, nanogel, hydrogel, cryogel chemistries, and processes to make it porous.

### II.B.3 Ferroelectric Elastomers

Ferroelectric materials may be considered as a sub-set of dielectric elastomers. In examples herein, ferroelectric materials such as PVDF and other polymeric systems are utilized. These ferroelectric materials can be poled and aligned in an electric or magnetic field.

There are no limits on the choice of materials used to make the ferroelectric elastomer elements, nor are there any restrictions on the choice of construction techniques and architectures used. There are no constraints on the amount of dimensional change a ferroelectric elastomer element may undergo, as long as it serves its intended purpose.

### II.B.4 Heat Shrink Material; Cold Shrink Materials

A heat shrink or cold shrink material as an irreversible dimension-changing material may comprise one or more heat shrink or cold shrink materials. These heat shrink/cold shrink materials undergo a dimensional change (mechanical contraction) when an external thermal stimulus, or activator, (heat, cold etc.) is applied. It is this dimensional change that is exploited in the present disclosure to mechanically create the differential movement in a differential-movement transfer stamp of the present disclosure, such as the differential-movement transfer stamp 100 of FIG. 1, that effects release.

Heat shrink and cold shrink polymers are well known in the art. There are no limits on the choice of heat shrink and cold shrink polymer materials used to make the heat shrink/cold shrink elements, nor are there any restrictions on the choice of construction techniques and architectures used. The heat shrink and cold shrink materials might be organic, inorganic, or a hybrid (organic+inorganic) in composition. These materials may comprise solid or porous films and coatings. There are no constraints on the amount of dimensional change a heat shrink or cold shrink element may undergo, as long as it serves its intended purpose.

As an alternate material example, consider a pre-stressed elastomer (such as PDMS without the liquid crystal), which might also be used as a novel heat shrink material. When heated, the elastomer will dimensionally change to reduce or eliminate the resident stress that is pre-built in it. As such, any of the elastomeric materials cited earlier might also be used as a heat shrink material.

### II.B.5 Light-Activated Heat Shrink Materials

A light-activated heat shrink material as an irreversible dimension-changing material comprises one or more heat shrink materials doped with one or more light-absorbing materials. This light-activated heat shrink material undergoes a dimensional change (mechanical contraction) when an external stimulus, or activator, (light) is applied. The light is absorbed by the light-absorbing material generating heat, which in turn then causes a dimensional change in the underlying heat shrink material. It is this dimensional change that is exploited in the present disclosure to mechanically create the differential movement in a differential-movement transfer stamp of the present disclosure, such as the differential-movement transfer stamp 100 of FIG. 1, that effects release.

Heat shrink polymers are well known in the art. The doped light-absorbing materials in the heat shrink polymers may be organic or inorganic in composition. These light-absorbing materials may include, but not be limited to: carbon black, carbon nanotubes, other nano materials, quantum dots, graphite, graphene, azobenzene compounds, viologens, etc.). The light-absorbing materials may be broad band light absorbers, or narrow band light absorbers.

There are no limits on the choice of heat shrink polymer materials and corresponding doped light-absorbing material used to make the light activated heat shrink elements, nor are there any restrictions on the choice of construction techniques and architectures used. These materials may comprise solid or porous films and coatings. There are no constraints on the amount of dimensional change a light-activated heat shrink element may undergo, as long as it serves its intended purpose.

### II.B.6 Shape Memory Alloy Materials

A shape memory alloy material as a reversible or irreversible dimension-changing material may comprise one or more shape memory alloy materials. These shape memory alloy films undergo a dimensional shape change that can be pre-programmed in the film when an external stimulus, or activator, (light, heat, etc.) is applied. It is this dimensional shape change that is exploited in the present disclosure to mechanically create the differential movement in a differential-movement transfer stamp of the present disclosure, such as the differential-movement transfer stamp 100 of FIG. 1, that effects release.

A wide variety of shape memory alloys are known in the art. There are no limits on the choice of shape memory alloy material used to make the shape memory alloy elements, nor are there any restrictions on the choice of construction techniques and architectures used. There are no constraints on the amount of dimensional change a light activated heat shrink element may undergo, as long as it serves its intended purpose.

### II.B.7 Photoactivated Materials

### II.B.7.a Contracting Photoactivated Materials

A photoactivated material as an irreversible dimension-changing material may comprise one or more contracting photoactivated materials. that undergo a dimensional volumetric contraction when an external stimulus, or activator, (light, heat, etc.) is applied. It is this dimensional shape change that is exploited in the present disclosure to mechanically create the differential movement in a differential-movement transfer stamp of the present disclosure, such as the differential-movement transfer stamp 100 of FIG. 1, that effects release.

As is well known in polymer art, shrinkage is observed during both the polymerization and the crosslinking (curing) of monomers and prepolymers. One of the main reasons for volume shrinkage is that the monomers are moving from van der Waals distance to covalent distance when a covalent bond is formed during polymerization.

Photoactivated materials may include: UV curable adhesives & epoxies such as, but not limited to: polyester-based UV adhesives, anaerobic adhesives, aerobic acrylic adhesives, mercaptoesters and acrylic modified epoxies, single & multi-part silicone, RTV silicone, UV aerobic acrylic urethane, single & multi-part epoxy resin, cyanoacrylate, hot melt acrylic polymers, etc.

Photoactivated materials may include photoresist media, such as, but not limited to: positive resist, negative resist, SU-8 and SU series of resists, KMPR, photosensitive polyimides, hybrid resists, organic/inorganic hybrid resist photo-emulsions, photo-polymers, block co-polymers, organic/inorganic hybrid polymers such as, but not limited to: Ormocer, Ormocomp, Ormoclear, etc.

Two or more photoactivated photoresist materials may be used together with one another. The two or more photoresist materials may be similar or dissimilar (all are positive resists, or all are negative resists, or some are positive resists and others are negative resists). The two or more photoresist materials may be deposited as separate discrete layers atop each other, or the one or more photoresist materials may be mixed (co-mingled) and then deposited as a single or multilayer film. These one or more photoresist materials may be activated by the same wavelength, or they may be actuated by different wavelengths. The one or more photoresist materials may be activated by UV light, visible light, NIR light, radiation, thermal heat, etc. The activation energy may fall uniformly or non-uniformly on the photoresist material.

Furthermore, the inert resin (or epoxy) in the photoactivated photoresist material might be made porous (entrapped with air) if so desired. For example (but not limited to), the inert resin (or epoxy) matrix may be perforated using aerogel, xerogel, nanogel, hydrogel, cryogel chemistries and/or processes to make it porous.

In the example above, light-initiated polymerization is discussed. However, photoactivated chemical compositions that undergo volume shrinkage on exposure to radiation, thermal energy, heat, electricity, moisture, chemistry etc., may also be used using the teachings of this work.

There are no limits on the choice of photoactivated material used to make the photoactivated elements, nor are there any restrictions on the choice of construction techniques and architectures used. There are no constraints on the amount of dimensional change a photoactivated element may undergo, as long as it serves its intended purpose.

### II.B 0.7.b Expanding Photoactivated Materials

A photoactivated material as an irreversible dimension-changing material may comprise one or more photoactivated materials that undergo a dimensional volumetric expansion when an external stimulus, or activator, (light, heat, etc.) is applied. It is this dimensional shape change that is exploited in the present disclosure to mechanically create the differential movement in a differential-movement transfer stamp of the present disclosure, such as the differential-movement transfer stamp 100 of FIG. 1, that effects release.

Expanding monomers are well known in polymer art. There are no limits on the choice of photoactivated material used to make the photoactivated elements, nor are there any restrictions on the choice of construction techniques and architectures used. There are no constraints on the amount of dimensional change a photoactivated element may undergo, as long as it serves its intended purpose.

As an example, consider PDMS, which is a silicone elastomer. PDMS is a liquid pre-polymer at room temperature. To fabricate a differential-movement transfer stamp, the PDMS pre-polymer may mixed with a curing agent and then cured to crosslink the polymer (if the curing agent is a UV activated curing agent), then the UV activated crosslinking process will cause a volume shrinkage in the material. Additional examples may be a PDMS pre-polymer with a thermal curing agent and a UV photo-initiator. Such a composition is also called “photo-definable PDMS”.

One or more of the actuating chemistries and principles revealed in this work may be used together as desired.

### II.C Anti-bonding Agent

Optional coating 116 of the example differential-movement transfer stamp separating first component 108 from second component 112 may be composed of an anti-bonding agent. An anti-bonding agent may be composed of anti-stick coating materials, also called “low surface energy coatings,” which are materials that exhibit low coefficient of friction. Low surface energy coatings may be organic or inorganic in composition. Organic compositions may include, but are not limited to, the following examples: polytetrafluoroethylene (PTFE), amorphous fluoropolymers like Teflon® AF, Cytop®, fluorinated silane-based monomers, etc.

Inorganic compositions may include, but be limited to, the following examples: materials such as natural and artificial diamonds, high pressure synthetic diamonds, graphite, molybdenum disulphide; coatings such as chemical-vapor-deposited (CVD) diamond, and diamond like carbon (DLC), hydrogenated amorphous carbon, a-C:H, a-C:H/a-Si:O, amorphous carbon, a-C, Cubic boron nitride (c-BN), hexagonal BN, CrN, TiN, TiCN, TiAlN, graphite, MoS2, Y2O3, ZrO, carbon, WS2 (tungsten disulfide), DLC nanocomposite coatings of WC and WS2; nanoparticles/quantum dots of MoS2, graphite, etc.; soft metallic films or coatings of lead, gold, silver, indium, copper, zinc, tin and bismuth, among other inorganic compositions.

Additionally, surface conversion for anti-sticking properties can also be effected by treating a coating with fluorine, ion doping, UV and DUV treatments, etc. All these processes attempt to lower the surface free energy of a coating. Anti-sticking properties can also be mimicked by utilizing materials with weak polarity+surface structure (so called “lotus effect”), and surface texturing.

There are fundamentally no limits on the thickness of the low surface energy coating layers. They may be as thin as a few angstroms to several tens of microns thick. Low surface energy coating layers may be deposited by any known conventional deposition means. Two or more of the materials listed may be combined and/or deposited together.

While certain representative embodiments have been shown for purposes of illustrating the variety of anti-bonding agents, it will be apparent to those skilled in the art that other materials not disclosed herein may be used without departing from the scope of the invention.

### II.D Non-Dimension-Changing Materials

When provided to one or the other of the first and second components 108, 112 of the example differential-movement transfer stamp 100, one or more non-dimension-changing materials may be rigid or flexible and may be composed of one or more polymers, one or more ceramics, one or more metals, one or more papers, one or more fabrics, or one or more glasses, or any combination thereof, among other things. Such non-dimension-changing material(s) may be transparent, opaque, or translucent, or any combination thereof. Each non-dimension-changing material may be a conductor, an insulator, or a semiconductor, or any combination thereof. Each material may be inorganic or organic or a combination thereof and may be single crystal, polycrystalline, oriented (or textured) polycrystalline, or amorphous in morphology. In some cases, the non-dimension-changing material may be identical to material for the substrate 104. In some cases, the substrate 104 may be monolithic and/or monolithically unitary (i.e., fabricated from a single piece of material) with the one of the first and second components 108, 112 containing the non-dimension-changing material.

A non-dimension-changing material used for a differential-movement transfer stamp may be porous or non-porous or a combination thereof. The pores (not shown), if present, may be created artificially or may exist naturally. The pores may be randomly located or deterministically placed. There are fundamentally no limits on the size and shape of the pores in the non-dimension-changing material.

There are fundamentally no limits on the thickness of the non-dimension-changing material deployed in the first or second component 108, 112, and in some embodiments the thickness may range from a few hundreds of nanometers, to several microns to hundreds of microns to several millimeters as desired by the application at issue. A non-dimension-changing material of this disclosure may be deposited by any known conventional deposition means. Two or more of the materials listed may be combined and/or deposited together.

While certain representative examples have been mentioned for purposes of illustrating the wide variety of non-dimension-changing materials that can be used for either of the first and second components 108, 112, it will be apparent to those skilled in the art that non-dimension-changing materials not disclosed herein may be made without departing from the scope of the invention.

### II.E Optional Agent(s) on First and/or Second Components

Optional agent(s) 124 on the first component 108 and optional agent(s) 128 on the second component 112, when provided, may be chosen to enhance the performance of the differential-movement transfer stamp 100. These coatings may be selected, according to their desired functionality, to increase or decrease the bonding strength of the reversible bonding, prevent damage to the underside of the removably secured microelectronic-device die, or microelectronics substrate, assist in release of the reversibly bonded microelectronic-device die, extend the lifetime of the differential-movement transfer stamp, etc. Optional agent(s) 124, 128 may include one or more functional materials, such as sealing gasket materials, adhesive materials, magnetic films, electret films, and liquid layer, among others.

### II.E.1 Sealing Gasket

If provided, agent(s) 124, 128 may comprise one or more of the following materials: metals such as copper, aluminum, indium, gallium, solders, eutectics, gold, nickel, vanadium, platinum, graphite (graphene), among others; organic compounds such as nitrile, nitrile rubber, fluorocarbon, fluorosilicone, ethylene propylene, perfluoro elastomer, perfluorinated elastomer, silicone, silicon rubbers, butyl, neoprene, isoprene, chloroprene, polyurethane, rubber, etc. A purpose of this agent is to act as a compressible cushion so that even if the surface quality/features of the first or second component 108 and 112 of the differential-movement transfer stamp 100, and the surface of the microelectronics device-die, wafer, substrate, etc., are not perfect, when the surfaces are reversibly secured, they may allow the formation of a vacuum seal and/or suitable engagement. Note that the metal layers (if used) are not used to bond/solder the two surfaces; they simply act as compressible seals in this usage.

### II.E.2 Adhesive Layer

If provided, agent(s) 124, 128 may comprise of an adhesive layer. The adhesive layer material may be naturally occurring or synthetic. The adhesive layer material may be organic, inorganic, or hybrid in composition. The adhesive layer material may comprise of monomers, polymers in composition. The adhesive layer material may be one part, or multi-part compound. The adhesive layer may be single use or multi-use. Preferably, the adhesive material has a relatively low tack (low adhesion force). Preferably, the adhesive material does not leave residue (or leaves minimum residue), on the microelectronic-device die/semiconductor wafer, etc., post its release.

Some examples of adhesive materials include, but are not limited to: natural materials such as plant resins, animal by-products, collagen, rubber, honey, syrup, pitch, cement; synthetic materials such as non-reactive adhesive materials like pressure sensitive adhesive (PSA), solvent based adhesives, polymer dispersion adhesives, contact adhesives, hot melt adhesives (thermoplastics), glues, parylenes. multi-part adhesives—reactive adhesives such as acrylics, cyanoacrylates, RTV, silicones, PDMS, elastomers, urethanes, epoxies, emulsions, thermosetting polymers, polyester resin—polyurethane resin, polyols—polyurethane resin, acrylic polymers—polyurethane resins. These may also include water or solvent soluble adhesive, etc. The adhesive chemistries may be cured/activated using plasma, light, UV, temperature, pressure, anaerobic environment, moisture, etc.

The “tack” or adhesive force of the adhesive layer may be tuned as desired post deposition of the layer, for example, by exposure to UV radiation, etc.

There are fundamentally no limits on the thickness of the adhesive layer and may range from a few nanometers to several microns or more as desired by application.

The adhesive layer may be deposited on the dimension-changing material surface (either the first component or the second component) using any known deposition technique. For example, the adhesive layer may be deposited by a deposition means such as, but not limited to: PVD, filament evaporation, RF heating, electron beam, ion assisted electron beam, sputtering, diode sputtering, magnetron sputtering, DC sputtering, bias sputtering, RF sputtering, CVD/thermal CVD/LPCVD/PECVD/APCVD/HDPCVD/ECR-PECVD/LTPECVD/MOCVD/PVD/hot-wire CVD, sol gel, evaporation, molecular beam (MBE) evaporation, molecular vapor deposition (MVD), ALD, ion-plating, electro-plating, dip-plating (dipping), hot dipping, and electroless-plating. Other coating processes, such as a Langmuir-Blodgett process, spin-coating process, spray-coating process, and roll-on coating process; printing processes, transfer processes, ink-jet processes, and powder-jet processes, etc., may also be utilized.

While certain representative embodiments have been shown for purposes of illustrating a point, it will be apparent to those skilled in the art that adhesive layer materials not disclosed herein may be used without departing from the scope of the invention.

### II.E.3 Magnetic Layer

If provided, agent(s) 124, 128, may comprise a magnetic or paramagnetic material. If the microelectronics-device die or microelectronics substrate, etc., can be coated with a functional material (material that has intrinsic use and purpose in the final device) that is magnetic or paramagnetic, then such a structure can be removably secured by using one or more permanent magnetic coating(s) as agent(s) 124 and/or 128 on the top surface of the first or second component 108, 112 of the differential-movement transfer stamp 100. Techniques for making permanent magnetic coatings are well known in literature and not elaborated on here.

### II.E.4 Electret Layer

If provided, coating(s) 124, 128, may comprise an electret layer. Electrets are dielectrics that retain an electric moment even after the externally-applied field has been reduced to zero. Heaviside, in 1885, coined the term “electret” by analogy to the established term magnet.

Many electret materials are in common use, for example: PVC (poly vinyl chloride), PS (polystyrene), PE (polyethylene), PETP (polyethylene terephthalate), PTFE (polytetrafluoroethylene), PVDF (polyvinylidene difluoride), amorphous TEFLON® type PTFE, and COCs (cyclic olefin co-polymers), among others.

As is well known in the art, charged particles create electric fields. This electric field has a magnitude and a direction. Electro-static electric field/force exerted by an electret coating can be used to removably secure a microelectronic-device die or microelectronic substrate by depositing one or more electret coating(s) on the top surface of the first and/or second components 108, 112 of the differential-movement transfer stamp 100. Techniques for making electret coatings are well known in literature and not elaborated on here.

In-lieu of using an electret, electrical charges (and hence voltage) can be created in-situ, for example, by coating the surface of a microelectronic-device die, semiconductor wafer, etc., with a photoconductive coating and then exposing this coating to an appropriate spectrum of light (hence photoconduction). Alternatively, this photoconductive coating could also be deposited on the top surface(s) of the first and/or second components 108, 112 of the differential-movement transfer stamp 100. A wide variety of semiconductor materials (organic, inorganic, and hybrid) are known in the art for photoconduction and are not repeated here for brevity.

### II.E.5 Liquid Layer

If provided, coating(s) 124 and 128, may comprise a liquid layer. Capillary forces exerted by this liquid layer can be used to removably secure a microelectronic-device die, semiconductor wafer, etc. This liquid layer 124 and 128 can reside on the top surface of the first or second component 108 and 112 of the differential-movement transfer stamp 100. The liquid layer can be organic or inorganic or hybrid in composition. Furthermore, the liquid layer might also have a gel-like consistency.

In-lieu of using static capillary forces, electrocapillarity or electrowetting on dielectric may also be used. Electrocapillarity is the modulation of capillarity using an electric voltage, which was first described in detail in 1875 by Gabriel Lippmann. Electrowetting on dielectric is an advancement of electrocapillarity and is the idea of using a thin insulating layer to separate the conductive liquid from the metallic electrode in order to eliminate the problem of electrolysis/hydrolysis.

### II.F Specific Example Differential-Movement Transfer Stamps

### II.F.1 Example Differential-Movement Transfer Stamp Having Optional Coatings

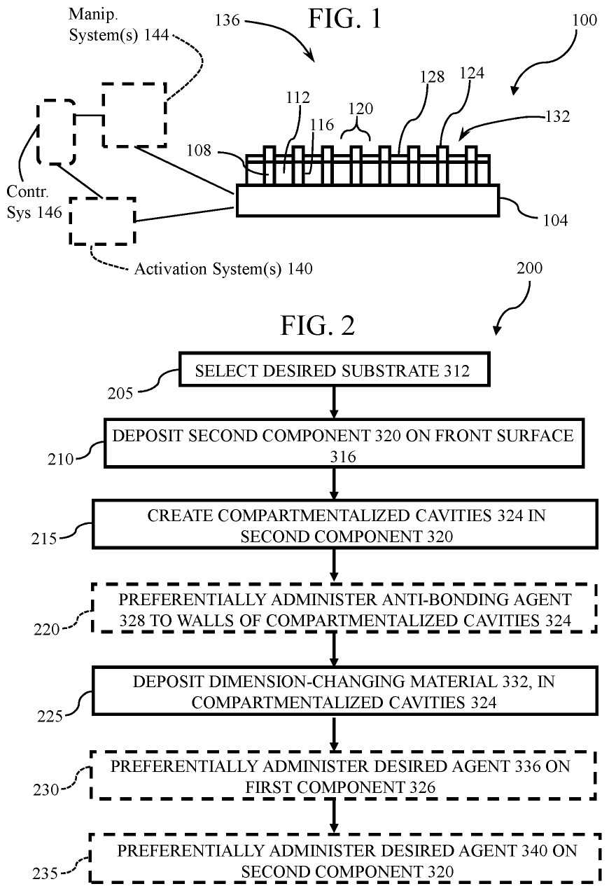

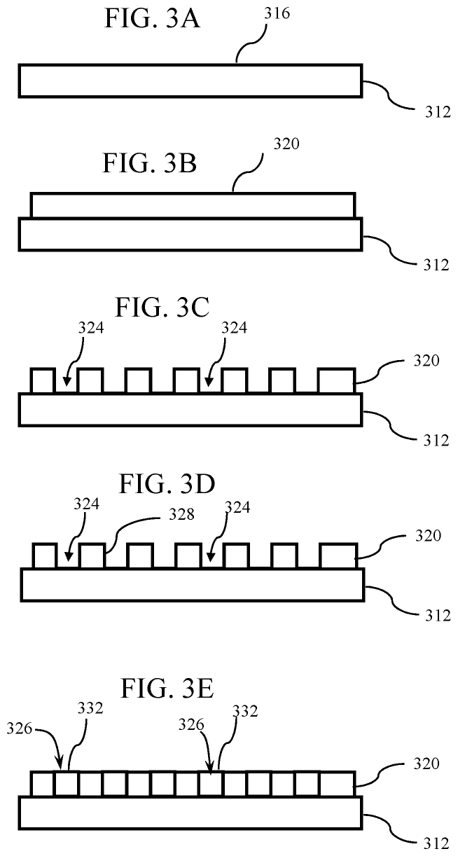

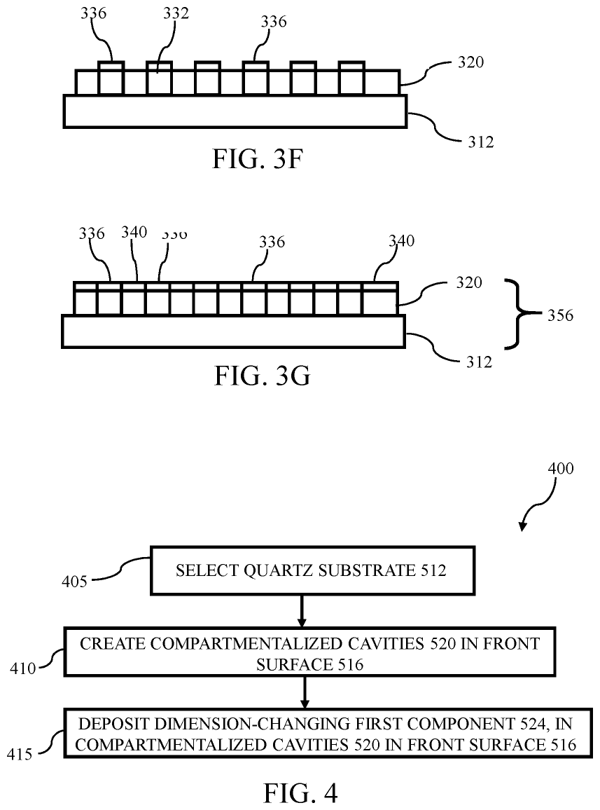

As a particular example of the foregoing general descriptions, FIG. 2 and FIGS. 3A to 3G illustrate a method 200 of forming an embodiment of the differential-movement transfer stamp 100 of FIG. 1, with FIG. 3G illustrating the particular components of the differential-movement transfer stamp 356 resulting from performing the method 200 of FIG. 2. As will become apparent from reading on, the activities of the blocks of the method 200 need not necessarily be performed in the order presented to achieve an equivalent result.

Referring now to FIGS. 3A to 3G, and also to FIG. 2, at block 205 of the method 200, a suitable substrate 312 (FIG. 3A) is selected based on factors and criteria discussed elsewhere in this disclosure. After substrate 312 has been selected, at block 210 a second component coating 320 (FIG. 3B) is deposited atop a surface 316 of the substrate 312. At block 215, a plurality of compartmentalized cavities 324 (FIG. 3C) are created in the second component coating 320.

Each compartmentalized cavity 324 in the second component coating 320 may be a region wherein a portion of the second component coating is removed to form a well, depression, or like void. Compartmentalized cavities 324 may be created using any one or more of a variety of techniques, such as wet chemical etching processes, electrolyte anodizing of semiconductors, dry etching processes such as reactive ion etching (RIE), plasma/planar etching, plasma enhanced etching (PE), inductively coupled plasma etching (ICP), deep reactive ion etching (DRIE), sputtering, ion enhanced etching, ion beam milling, chemically assisted ion beam milling, electron cyclotron resonance plasma (ECR), high density plasma (HDP), microwave and RF plasma assisted etching, laser induced/assisted chemical etching, may be employed for the same effect. The chemical source maybe introduced as flood, time-varying, spatially varying, or continuous. Compartmentalized cavities 324 may be created by one or more alternative techniques, such as laser ablation, laser photo-ablation, laser induced etching, laser assisted direct imprint (LADI), laser chemical etching, femto-second laser ablation and other ultra-fast laser based etching phenomenon.

Each compartmentalized cavity 324 in the second component coating 320 is distinct from a thru hole in that the cavity 324 does not extend through the entire thickness of the substrate 312. (See, e.g., FIG. 3C). That said, as described below, some techniques for making the differential-movement transfer stamp 100 (FIG. 1) can involve providing a layer containing thru-holes in one or more layers that are then mated with another layer that closes one end of the thru-holes. There are no limits on the depth of each compartmentalized cavity 324 in relation to the thickness of the second component 320. There are no restrictions on the shape, size, and pitch of the compartmentalized cavities 324. The plurality of compartmentalized cavities 324 created in the second component coating 320 may be identical through the entire thickness of the second component coating, or the shape and size of the compartmentalized cavities 324 created in second component coating may not be identical for the entire thickness of the second component coating.

The plurality of compartmentalized cavities 324 can be positioned with sub-micron accuracy down to even sub nanometer accuracy relative to their desired spatial positions, depending on the choice of the second component coating 320 and the choice of patterning and formation techniques. The plurality of compartmentalized cavities 324 can be made of any size from sub-micron diameters to several microns, to 10s of microns in diameter. There are no fundamental limits on the size of compartmentalized cavities 324. This is dictated by the particular application. After formation of the compartmentalized cavities 324, the portions of the second component coating 320 remaining can function as one or more of the second components 112 of differential-movement transfer stamp 100 of FIG. 1.

The plurality of compartmentalized cavities 324 can be made of any geometrical shape. The shape and size of the plurality of compartmentalized cavities 324 may be identical through the entire thickness of the second component 320, or the shape and size of the plurality of compartmentalized cavities 324 may not be identical for the entire thickness of the second component 320. The plurality of compartmentalized cavities 324 can be as close or as far apart from each other. The plurality of compartmentalized cavities 324 can be separated from each other by 10s of microns, or less than a micron, or sub-micron, as dictated by intended application. There are fundamentally no restrictions on the surface quality of the plurality of compartmentalized cavities 324.

While certain representative features of the compartmentalized cavities 324 have been mentioned for purposes of illustrating aspects the invention, it will be apparent to those skilled in the art that other features may be incorporated in the compartmentalized cavity 324 without departing from the scope of the invention, which is defined in the appended claims.

At optional block 220, an anti-bonding agent 328 (FIG. 3D) can be applied, for example, preferentially, to the walls of the compartmentalized cavities 324.

At block 225, a dimension-changing material 332 (FIG. 3E) is deposited in the compartmentalized cavities 324 to form a corresponding plurality of the first components 326, which correspond to the first components 108 of the differential-movement transfer stamp 100 of FIG. 1. The dimension-changing material 332 may be deposited by any known conventional deposition means as desired. A few nonlimiting deposition techniques that may be used include, but are not limited to: spin-coating process, spray-coating process, Langmuir-Blodgett process, sol gel, roll-on coating process; printing processes; transfer processes; ink-jet processes; and powder-jet processes, etc. may also be utilized. Two or more of the dimension-changing materials 332 listed may be combined and deposited together. These two or more dimension-changing materials 332 may be activated by the same or different stimulus(i), or activator(s). There are fundamentally no limits on the thickness of the dimension-changing material 332 in a direction normal to the working surface of the differential-movement transfer stamp 356. It may be as thin as a few hundred nanometers to several tens of microns thick or more.

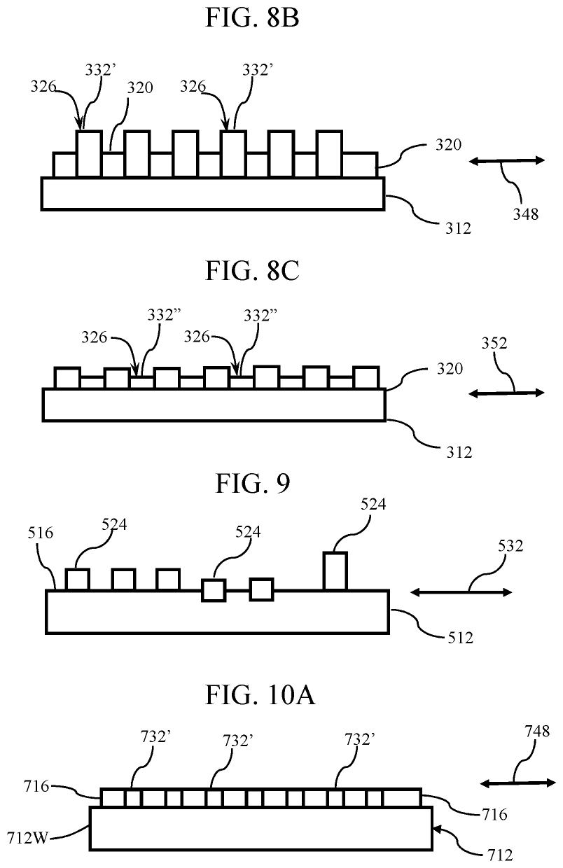

Referring briefly to FIG. 8A-8C, FIG. 8A illustrates the dimension-changing material 332 of the first components 326 in the compartmentalized cavities 324 substantially flush (designated by double-arrow-headed line 344) with height of the second component 320. FIG. 8B illustrates the dimension-changing material 332′ of the first components 326 higher (designated by double-arrow-headed line 348) than the height of the second component 320. FIG. 8C illustrates the dimension-changing material 332″ of the first components 326 substantially lower (designated by double-arrow-headed line 352) than the height of second component 320.

At optional block 230, an agent 336 (FIG. 3F; see also optional agent(s) 124 of FIG. 1) is preferentially applied to the dimension-changing material 332, i.e., the first components 326. At optional block 235, an agent 340 (FIG. 3G; see also optional agent(s) 128 of FIG. 1) is preferentially deposited on the second component 320.

### II.F.2 Example Economical Differential-Movement Transfer Stamp

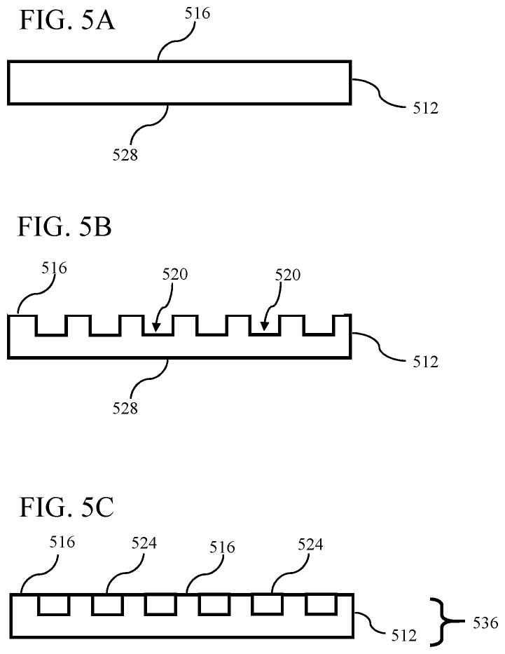

As another particular example of the above general descriptions, FIG. 4 illustrates a method 400 of forming an embodiment of the differential-movement transfer stamp 100 of FIG. 1, with FIG. 5C illustrating the particular components of the differential-movement transfer stamp 536 resulting from performing the method of FIG. 4. As will become apparent from reading on, the activities of the blocks of the method 400 need not necessarily be performed in the order presented to achieve an equivalent result.

Referring now to FIGS. 5A to 5C, and also to FIG. 4, at block 405 of the method 400, a monolithic quartz substrate 512 (FIG. 5A) is selected. Quartz or fused silica wafers are widely available, large in area, (200 mm in diameter and even greater) and relatively low cost. Furthermore, there is a large existing quartz and silicon manufacturing base that can shape and tailor quartz substrates (e.g., wafers and other bodies) and their surfaces with very high precision at low cost. Furthermore, by leveraging existing silicon processes it is possible to create micron sized and nanometer sized cavities in quartz readily. In lieu of quartz, a glass substrate 512, for example, may be used.

In some embodiments, the substrate 512 and its associated thickness chosen for the differential-movement transfer stamp 536 (FIG. 5C) has high rigidity, whereas in other embodiments, the substrate 512 and its associated thickness chosen for the differential-movement transfer stamp is flexible and conformal.

It can also be advantageous to manufacture the substrate 512 of the differential-movement transfer stamp 536 (FIG. 5C) with very high levels of optical flatness (both local and global) and with high levels of parallelism between the front and back surfaces 516, 528, respectively, of the differential-movement transfer stamp. There are no constraints or absolute values on this flatness and parallelism, and the desired values are typically dependent on the end application. It further can be advantageous to polish both the front and back surfaces 516, 528, respectively, of the substrate 512 to a very low surface roughness. There are no constraints or absolute values on this surface roughness figure and the desired values are typically very dependent on end application. The back surface 528 of the substrate 512 could just be left ground and not polished, if so desired.

After the substrate 512 has been selected, compartmentalized cavities 520 (FIG. 5B) can be create in the front surface 516 of the substrate at block 410. In this example, the substrate 512 also serves as a second component 112 (FIG. 1) of the differential-movement transfer stamp 100 of FIG. 1. At block 415, a dimension-changing material 524 (FIG. 5C) is deposited in the compartmentalized cavities 520 so as to function as first components 108 (FIG. 1).

The dimension-changing material 524 of the first components 108 may be individually controlled or controlled in one or more groups in the same or similar manner(s) described elsewhere herein. In addition, any one or more of coatings 124 and 128 (FIG. 1) may be incorporated into method 400 of FIG. 4 as desired to suit a particular application.

In the example shown, the upper (relative to FIG. 5C) surfaces of the dimension-changing material 524 are substantially in-plane with one another and the front surfaces 516 of the substrate 512, which here function as the second component(s) 112 of the differential-movement transfer stamp 100 of FIG. 1. Referring briefly to FIG. 9 for illustration of in-planeness versus out-of-planeness, substantially in-plane (designated by double-arrow-headed line 532) refers to the height difference between the top and bottom (relative to FIG. 9) of the dimension-changing material 524 of any of the first components 108 and the front surface 516 of the substrate 512, with this height difference being less than 1 mm for in-planeness. When the height difference is equal to or greater than 1 mm, the dimension-changing material 524 of a corresponding one of the first components 108 is considered substantially out-of-plane. Although substantially in-plane dimension-changing material components 524 are depicted in FIG. 5C from performance of the method 400 of FIG. 4, the dimension-changing material 524 of any one or more of the first components 108 could also be substantially out-of-plane.

### II.F.3 Example Differential—Movement Transfer Stamp Having Multilayer Substrate Body

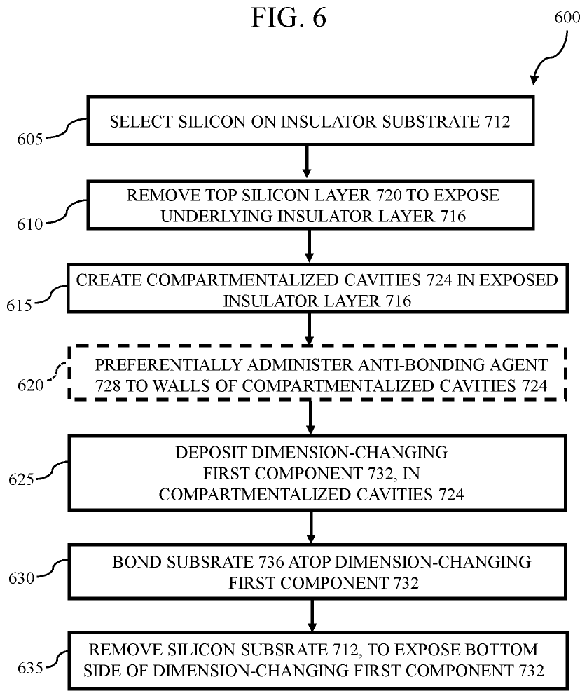

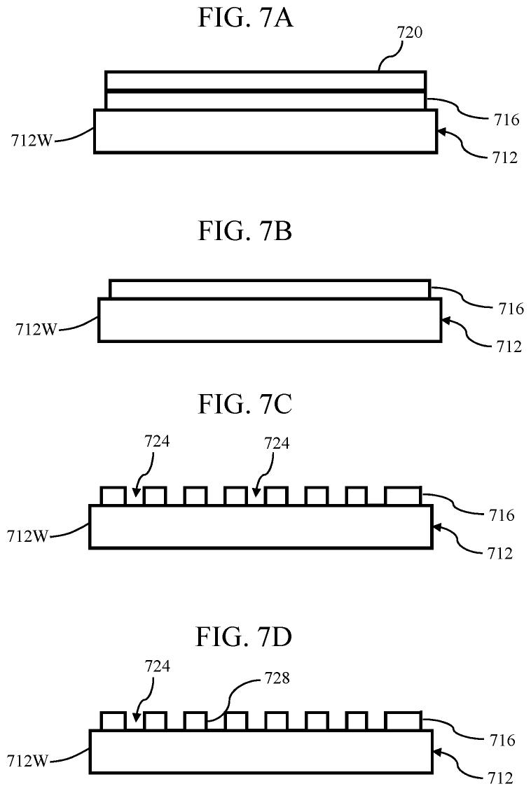

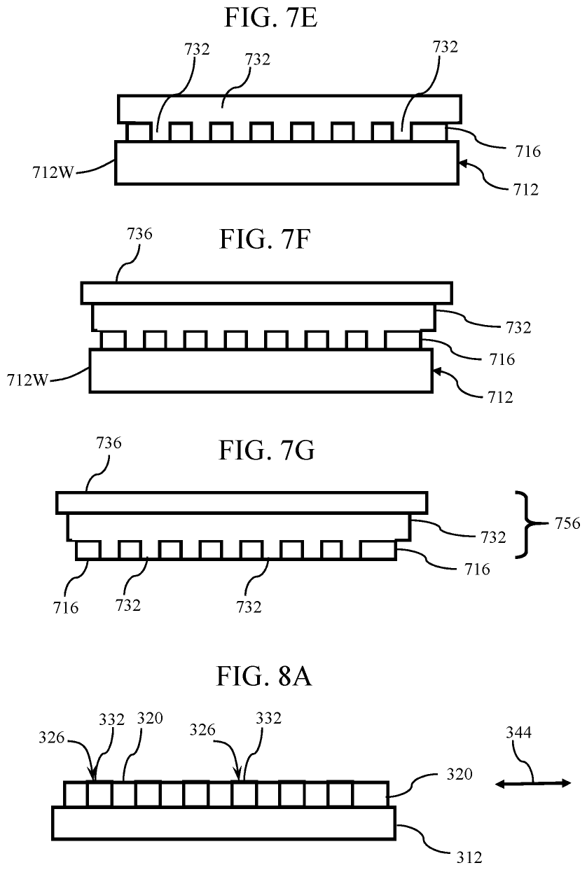

As another particular example of the above general descriptions, FIG. 6 illustrates a method 600 of forming a differential-movement transfer stamp 100 of FIG. 1, with FIG. 7G illustrating the particular components of the embodiment of the differential-movement transfer stamp 756 resulting from performing the method of FIG. 6. As will become apparent from reading on, the activities of the blocks of the method 600 need not necessarily be performed in the order presented to achieve an equivalent result.

Referring now to FIGS. 7A to 7G, and also to FIG. 6, at block 605 of the method 600, a first substrate 712 (FIG. 7A) is selected. The first substrate 712 is a silicon on insulator substrate, which comprises a silicon wafer 712W, an insulating layer of silicon dioxide 716, and a silicon layer 720, respectively. After selecting first substrate 712, at block 610, the silicon layer 720 is removed to expose top of the insulating layer of silicon dioxide 716 (FIG. 7B). At block 615, a plurality of compartmentalized cavities 724 (FIG. 7C) can be created in insulating layer of silicon dioxide 716. At optional block 620, an anti-bonding agent 728 (FIG. 7D) can be preferentially applied to the walls of the compartmentalized cavities 724. At block 625, a dimension-changing material 732 (FIG. 7E) is deposited in the compartmentalized cavities 724.

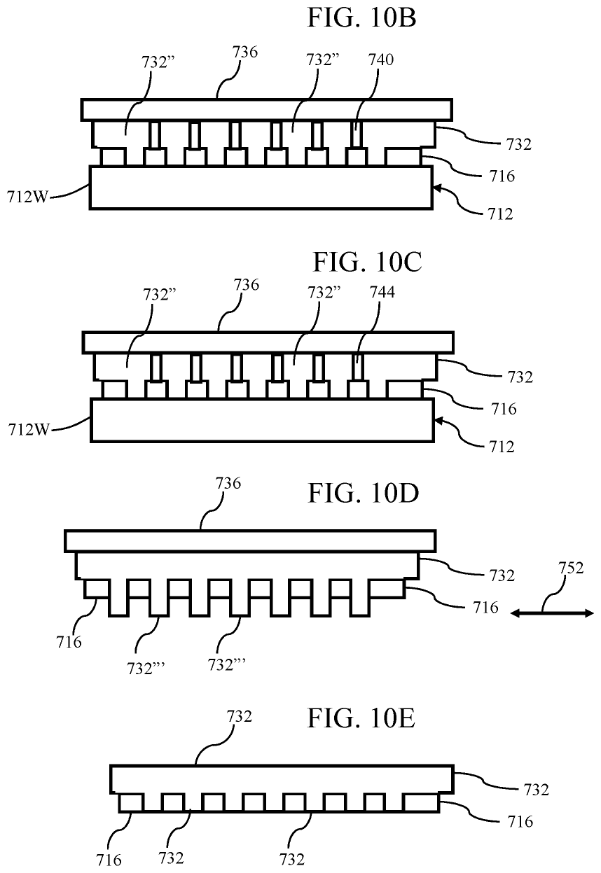

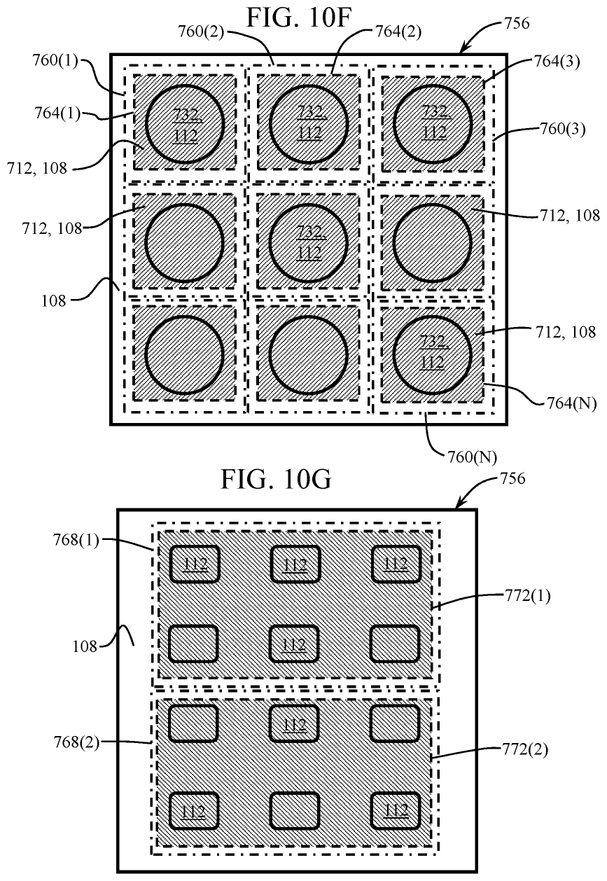

Referring briefly to FIGS. 10A-10C, FIG. 10A illustrates the top of a dimension-changing material 732′ substantially flush (designated by the double-arrow-headed line 748) with height of the silicon dioxide layer 716. FIG. 10B illustrates a dimension-changing material 732″ patterned and non-continuous (see, e.g., gap 740 and like gaps) atop the silicon dioxide layer 716. FIG. 10C illustrates dimension-changing material 732″ patterned and non-continuous. The non-continuous region is backfilled with another material 744 atop the silicon dioxide layer 716.

Referring again to FIG. 6, at block 630 of the method 600, another substrate 736 (FIG. 7F) is bonded atop the dimension-changing material 732. The substrate 736 and its associated thickness can be chosen so that the resultant differential-movement transfer stamp is flexible and conformal. At block 635, the silicon substrate 712 (FIG. 7G) is removed to expose bottom side of the dimension-changing material 732.

Referring briefly to FIGS. 10D-10E, FIG. 10D illustrates the exposed bottom side of the dimension-changing material 732′″ substantially lower (designated by double-arrow-headed line 752) than the height of the silicon dioxide layer 716. FIG. 10E illustrates the differential-movement transfer stamp of the method 600 of FIG. 6, without the additional substrate 736 of FIG. 10C atop the dimension-changing material 732.

Referring to FIGS. 10F and 10G, FIG. 10F is a plan view of the differential-movement transfer stamp 756 of FIG. 7G and an example configuration of functional units 760(1) to 760(N) (only a few labeled to avoid clutter). Each functional unit 760(1) to 760(N) is indicated by a bounding box appearing in dash-dot lines. Each location of the dimension-changing material 732 corresponds to a respective one of the second components 112, and the silicon dioxide layer 712 corresponds to the first component 108. In this example, the silicon dioxide layer 712 is continuous except at the locations of the dimension-changing material. Consequently, it may be considered to be a single non-dimension-changing first component. In this example, each functional unit 760(1) to 760(N) includes a single second component 112, i.e., single location of the dimension-changing material 732 and a portion of the single first component 108. In one example use of the differential movement transfer stamp 756 of FIG. 10F, each functional unit 760(1) to 760(N) may be a die-receiving region intended to receive a corresponding microelectronic-device die 764(1) to 764(N) (only a few labeled to avoid clutter), which are denoted by bounding boxes in dashed lines. Those skilled in the art will readily appreciate that the pitch of the locations of the second components (again, the locations of the dimension-changing material 732), and correspondingly, the pitch of the microelectronic-device dies 764(1) to 764(N) may be any suitable pitch, including fixed and/or variable pitches. Those skilled in the art will also readily appreciate that the configuration and arrangement of functional units 760(1) to 760(N) illustrated can be used on any differential-movement transfer stamp made in accordance with the present disclosure. It is noted that the locations of the dimension-changing material 732 need not be circular as shown. Rather, they can be any shape desired. Similarly, the functional units 760(1) to 760(N) and/or the microelectronic-device dies 764(1) to 760(N) need not be rectangular; they can be any shape desired. In an alternative view, silicon dioxide layer 712 may be considered to have a plurality of first components 108, with each such first component not being a discrete component (like the second components 112 in this example) but rather being the portion of the silicon dioxide layer located with a corresponding functional unit 760(1) to 760(N). In other embodiments, discrete first components (not shown) can be provided in lieu a continuous first component 108. In some embodiments, the discrete second components 112 can be replaced by a continuous second component (not show), for example, similar to continuous first component 108.

As described elsewhere herein, each of the functional units 760(1) to 760(N) may be individually activated to release the corresponding microelectronic-device die 764(1) to 764(N) using any suitable type(s) activation system(s) 140 (FIG. 1). In this example, the second components 112 comprise the dimension-changing material 732, so these are the components that are activated to effect the releases. As also described elsewhere herein, in the example, the dimension-changing material 732 can be an expanding material or a contracting material, and one or more surface treatments (not shown) may be applied to one, the other, or both of the first and second components 108, 112 to provide the desired functionality, such as bonding and anti-bonding, among others.

FIG. 10G illustrates another configuration of functional units 768(1) to 768(N) (only two shown and labeled) and their relation to corresponding respective microelectronic-device dies 772(1) to 772(N) (only two shown and labeled). In the example shown, each functional unit 768(1) to 768(N) includes multiple ones of the second components 112 and a larger portion of the single first component 108 of FIG. 10F (under the first view discussed above relative to FIG. 10F). In this example, all of the second components within each functional unit 768(1) to 768(N) may be activated simultaneously, or nearly simultaneously, with one another so as to effect the release of the corresponding microelectronic-device die 772(1) to 772(N) using any one or more suitable types of activation system(s) 140 (FIG. 1). Other aspects of the elements illustrated in FIG. 10G may be the same as or similar to aspects of such elements as discussed above in connection with FIG. 10F. FIGS. 10F and 10G illustrate only a few configurations of functional units that can be used with a differential-movement transfer stamp made in accordance with the present disclosure. Many other configurations may occur to skilled artisans after reading and understanding this entire disclosure.

### II.G Example Uses of a Differential-Movement Transfer Stamp of the Present Disclosure

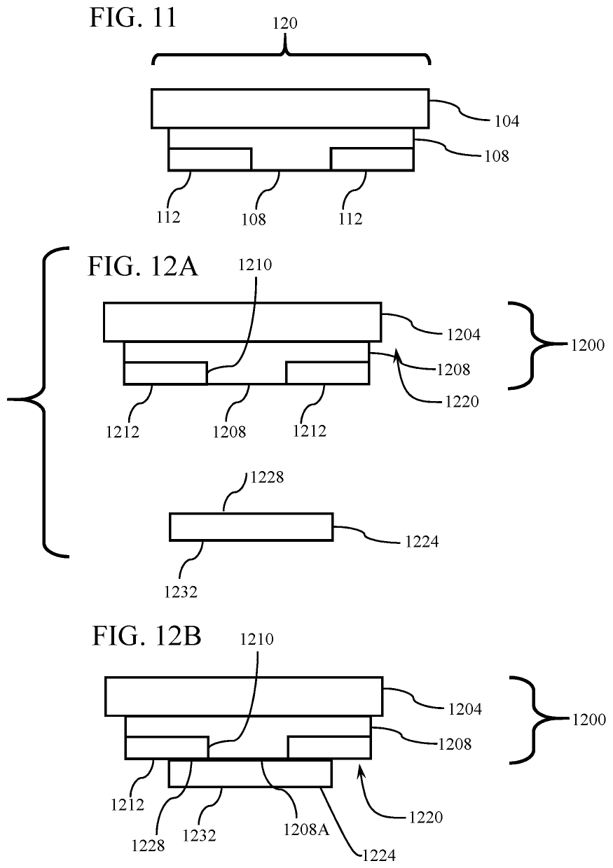

To clearly illustrate some features and aspects of a differential-movement transfer stamp of the present disclosure, such as differential-movement transfer stamp 100 of FIG. 1, FIG. 11 illustrates an upside down and rotated portion of the differential-movement transfer stamp 100 of FIG. 1. In this illustrative, but non-limiting, example, the differential movement transfer stamp 100 is configured so that the functional unit 120 includes a single first component 108 and the portions of the second component(s) 112 shown in FIG. 11. Of course, as described above relative to FIGS. 10F and 10G, the configuration of functional unit 120 in FIG. 11 is but one of many configurations possible.

FIGS. 12A-12B through FIGS. 15A-15C illustrate various aspects and features utilizing a basic structure of the differential-movement transfer stamp 100 (FIG. 1) in removably (also, reversibly) securing a microelectronic-device die to the differential-movement transfer stamp. For the ease of illustration, all of these examples are simplified by using the single-second component functional unit 120 illustrated in FIG. 11. However, the aspects and features illustrated in the FIGS. 12A-12B through 15A-15C may be incorporated into any suitable differential-movement transfer stamp disclosed herein.

### II.G.1 Surface-Activation Bonding

FIG. 12A illustrates an example of a differential-movement transfer stamp 1200 that includes a substrate 1204, a first, dimension-changing, component 1208 on top of the substrate 1204, and a second, non-dimension-changing, component 1212 atop the first component. The first component 1208 extends in a compartmentalized cavity 1210 formed in second component 1212 and is substantially flush with the surface of second component. One or more optional anti-bonding coatings (not shown) may be applied to the second component 1212 (FIG. 1, coating 128), as desired.

Confronting a working face 1220 of the first component 1208 is a microelectronic-device die 1224 having a front surface 1228 and a back surface 1232. As depicted, the front surface 1228 of the microelectronic-device die 1224 is facing the working face 1220 of the differential-movement transfer stamp 1200.

In this example, the front surface 1228 of the microelectronic-device die 1224 and the portion(s) of the working face 1220 of the differential-movement transfer stamp 1200 that will engage one another during the reversible bonding process may first be conditioned and prepped for bonding. A variety of techniques have been developed in the semiconductor industry to bond wafers of similar/dissimilar materials together at room temperature or low temperature, and one or more of these techniques may be deployed for the present conditioning and prepping. These techniques typically involve rigorous cleaning processes for the surfaces to be bonded, e.g., the front surface 1228 and on the working face 1220 (conditioning/preparing the surfaces to be bonded), in conjunction with plasma treatments of these cleaned surfaces (with or without reactive plasma species (activated plasma), atmospheric plasma, with or without inert gases, etc.). Either one or both of the surfaces to be bonded may be conditioned, as desired. In some examples, the surfaces may be in their natural state without need for any modification. The resultant bonding is called “van der Waals bonding” or “bonding due to intermolecular forces.”

FIG. 12B illustrates a reversible securing process, wherein the front surface 1228 of the microelectronic-device die 1224 is reversibly bonded to the working face 1220 of the differential-movement transfer stamp 1200, in this example, the front surface 1208A of the dimension-changing first component 1208. This can be accomplished, for example, by bringing the microelectronic-device die 1224 proximate to the differential-movement transfer stamp 1200 at the front surface 1208A of the first component 1208, or vice versa, and holding them proximate or in intimate contact with each other. In this example, the microelectronic-device die 1224 is bonded to the front surface 1208A of the working face 1220 of the differential-movement transfer stamp 1200 due to the prepped surface chemistries of these cleaned surfaces, and the bonding occurs so called “spontaneously.” This bonding only occurs between microelectronic-device die front surface 1228 and the front surface 1208A of the dimension-changing first component 1208.

The bonding between the differential-movement transfer stamp 1200 and the microelectronic-device die 1224 can occur under controlled ambient (vacuum environment, elevated or low temperature, etc.) or at room temperature. Initial bonding strength is dependent on many factors including nature and quality of the cleaning, additional surface preparations (flatness, roughness, additional chemical treatments), reactive surface species (hydrophobic, hydrophilic, etc.), environment, bonding temperature, etc. Both the front surface 1228 of the microelectronic-device die 1224 and the front surface 1208A of the dimension-changing first component 1208 of the differential-movement transfer stamp 1200 may be planar or non-planar prior to bonding. This bonding technique of FIG. 12A and FIG. 12B may be used along with the bonding technique revealed in further in this writeup, if so desired.

### II.G.1. A. Examples of Microelectronic-Device Die and Microelectronic Substrate

As an example of microelectronic-device die or microelectronic substrate 1224, consider an inorganic LED wafer below.

The starting growth substrate/platforms for III-V Nitrides (InGaN LEDs) are well known in prior art. Some of them, but not all, are outlined below: GaN on GaN, GaN on Sapphire, GaN on SiC, GaN on Si, GaN on AlN, GaN on Ga2O3, GaN on hBN, GaN on Graphene, GaN on Wse2, etc. The growth substrate can be transparent or opaque. The growth films, once grown can be processed further on the growth substrates into microLEDs.

Note that other substrates and GaN crystal orientations, such as cubic GaN on Si, or cubic GaN on Si on SiC also exist and can be utilized without restrictions. Similarly, LED in the UV, DUV, NIR, IR regions will have different base substrates and device layers and can be utilized without restrictions. Also note that there exist architectures that combine LEDs with a down conversion phosphor together as a monolithic and these and other types of devices can be used without restrictions.

A wide variety of III-V Nitride film growth techniques are known in prior art and in production. The growth techniques may involve any known conventional deposition means such as PVD processes such as: MBE or, CVD processes such as, but not limited to: MOCVD, HVPE, LPCVD, HDPCVD, ECR-PECVD/LTPECVD//PVD/, LPE, PLD, etc. The GaN/InGaN (III-V Nitride) might be Wurtzite or cubic in crystal phase.

A variety of device architectures exist for III-V Nitride LEDs and may include electro-luminescent devices in the form of simple P/N junctions, PIN junctions (homo and heterojunctions), single heterojunction, dual heterojunction, multi-heterojunctions, band-gap engineered Quantum confined structures such as: quantum wells, strained quantum wells, superlattices (Type I, Type II), quantum wires, quantum dots, quantum nanotubes (hollow cylinder), quantum nanowires (solid cylinder), quantum nanobelts (solid rectangular cross section), quantum nanoshells, quantum nanofiber, quantum nanorods, quantum nanoribbons, quantum nanosheets, etc.

Alternatively, the growth films can be transferred onto another, secondary substrate prior to being processed into microLEDs. It is understood that any known technique for removal of GaN/InGaN (III-V nitride) films from the growth substrate might be used. Some of these techniques for substrate removal and thin film transfer are cited below; note that this list is not comprehensive.

Laser lift off techniques may include using an excimer layer, using a YAG laser, etc. Techniques and absorbing layers have been developed such that thin film removal can be effected by using lasers from the UV-Vis-NIR-MWIR range of wavelengths. Chemical lift off techniques such as: photo-electro chemical etching (PEC etching), electro chemical etching, liquid etching, molten chemical etching, etc. The sacrificial growth layers may include, but not limited to, GaN, Ga₂O₃, CrN, ZnO, AlN.

Stress induced transfer techniques such as natural stress induced lift off, thermal stress induced lift off, ion implanted stress lift off, hydrogen/helium implanted stress lift off, etc., can be used. Mechanical stress induced transfer techniques can include deposition and physical peeling of the GaN/InGaN stack from a 2D sacrificial growth layer of hBN, MoS₂, MoSe₂, WS₂, graphene, mica, etc.

While certain representative LED device architectures have been illustrated, it will be apparent to those skilled in the art that other LED architectures and materials not disclosed herein may be used without departing from the scope of the invention.

While LED device architectures are elaborated on, it is self-evident that other electronic and opto-electronic devices manufactured in silicon (Si), silicon germanium (SiGe), germanium (Ge), silicon-on-insulator (SOI), silicon on sapphire, germanium on insulator, GaP, GaAs, etc., substrates could be utilized.

Electronic devices might include, but not limited to, devices such as RFIDs, MEMS, ICs, Photovoltaic Solar Cells (PV), display arrays, Focal Plane Arrays (Sensors), CMOS detectors, CCD detectors, Quartz oscillators, etc. The devices might work in any electro-magnetic/spectral region, from UV-Vis-NIR-MWIR-FIR spectral regions or beyond.

### II.G.2 Vacuum Generation

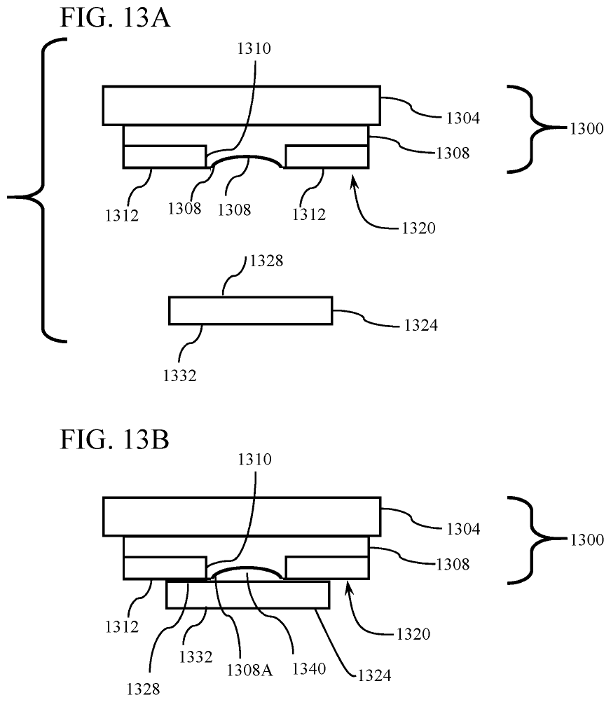

FIG. 13A illustrates another example of a differential-movement transfer stamp 1300 that includes a substrate 1304, a first, dimension-changing, component 1308 on top of the substrate 1304, and a second, non-dimension-changing, component 1312 atop the first component. The first component 1308 extends in a compartmentalized cavity 1310 formed in second component 1312 and is substantially flush with the surface of second component. Part of the dimension-changing second component 1308 is concave shaped, as depicted. One or more optional anti-bonding coatings (not shown) may be applied to the second component 1312 (FIG. 1, coating 128), as desired.

Confronting a working face 1320 of the first component 1308 is a microelectronic-device die 1324 having a front surface 1328 and a back surface 1332. As depicted, the front surface 1328 of the microelectronic-device die 1324 is facing the working face 1320 of the differential-movement transfer stamp 1300.

FIG. 13B illustrates the removably securing process, wherein the front surface 1328 of the microelectronic-device die 1324 is reversibly secured to the front surface 1308A of the concave shaped dimension-changing first component 1308 of the differential-movement transfer stamp 1300 so as to effectively form an assembly 1336. In this example, this may be accomplished by bringing the microelectronic-device die 1324 proximate to the differential-movement transfer stamp 1300, or vice versa, at the front surface 1308A of the dimension-changing first component 1308 and holding them firmly against each other during or post evacuating the gaseous component in the space formed due to the concave cavity 1340. The assembly 1336 is bonded due to differential pressure between the partial vacuum created in the concave cavity 1340 versus ambient pressure (atmospheric pressure, if atmosphere is the ambient).

Evacuation of the gaseous component(s) in the concave cavity 1340 can be performed using any of a number of active/passive techniques for generation of vacuum, as described below. One or more of the described techniques might be used together, if so desired.

One or more methods, which may be internal to the concave cavity 1340, for evacuating the gaseous component for generating vacuum may be used. Examples of such methods may include, but are not limited to the following.

Two substrates can be joined face to face, with one (or both) substrate(s) containing exposed depressions in/on its surface (cavities) facing the joining seam, in a vacuum environment. This physical joining can be performed with or without heating the joined assemblage. On removal from the vacuum chamber into air and at room temperature, the two substrates will be held, or bonded, together. Atmospheric pressure forces the substrates together due to the partial vacuum (removal of air/gas) created in the cavities.

Vacuum can be generated, in-situ, by heating/burning a pre-deposited pyrophoric substance in the concave cavity 1340 of the dimension-changing first component 1308. The contained volume of air in the concave cavity 1340 undergoes rapid gas expansion and leaks. Plugging the interface between the second component 1312 and microelectronic-device die front surface 1328 rapidly may be performed prior to cooling down of the remainder contained volume of air/gas, creates partial vacuum in the concave cavity 1340.

Vacuum can also be generated, in-situ, by employing one or more gas gettering materials, or “getters”, in the concave cavity 1340. For example, one or more getters can be deposited in the concave cavity 1340 of the dimension-changing first component 1308, then prior to joining the interface between the second component 1312 and microelectronic-device die front surface 1328 together, the getter(s) can be discharged (heated or otherwise activated (heat, light, moisture, electro-magnetic radiation, microwaves, etc.) to release their air/gas components). Post discharge, the microelectronic-device die 1324 will be reversibly bonded to the differential-movement transfer stamp 1300 because the getter(s) will re-adsorb any residual air/gas/moisture in the concave cavity 1340 creating partial vacuum.

Vacuum can also be generated, in-situ, by joining, at the joining interface therebetween, the second component 1312 and microelectronic-device die surface 1328 together. Subsequently annealing this joined assemblage at low/medium/high temperature to initiate a chemical reaction between the trapped gases in the concave cavity 1340 (or alternatively, a coating deposited in the concave cavity prior to joining) and the dimension-change first component 1308. Once the assemblage is cooled to room temperature, the microelectronic-device die 1324 will be reversibly bonded to the differential-movement transfer stamp 1300 because the chemical reaction and its by-products will reduce/remove the pressure of the trapped gases in the concave cavity 1340 creating partial vacuum.

Vacuum can also be generated, in-situ, if the dimension-changing first component 1308 is elastomeric (deformable). It is also possible to create “suction”, in which the gaseous component in the concave cavity 1340 is displaced when the dimension-changing first component 1308, having the concave cavity 1340, is pressed firmly against the microelectronic-device die 1324, for example, in the manner of an elastically deforming suction cup.

There are no limitations/requirements on the magnitude of the partial vacuum, as long as the level of vacuum is sufficient to create the desired effects and functionality of removably securing the microelectronics substrate. While certain representative embodiments have been shown for purposes of illustrating the wide variety of vacuum generating techniques, it will be apparent to those skilled in the art that techniques/methods not disclosed herein may be used without departing from the scope of the invention. This bonding technique of FIG. 13A and FIG. 13B may be used along with the bonding technique revealed above in connection with FIGS. 12A and 12B, if so desired.

### II.G.3 Adhesive Bonding

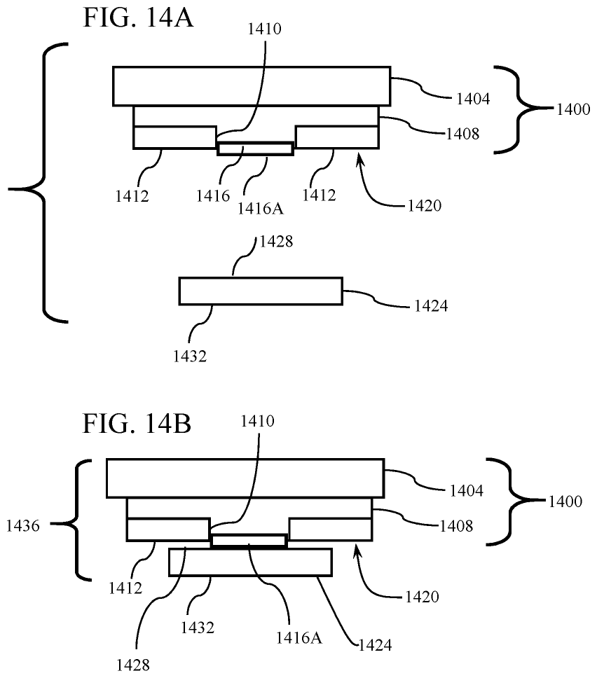

FIG. 14A illustrates another example of a differential-movement transfer stamp 1400 that includes a substrate 1404, a first, dimension-changing, component 1408 on top of the substrate 1404, and a second, non-dimension-changing, component 1412 atop the first component. The first component 1408 extends in a compartmentalized cavity 1410 formed in second component 1412 and is substantially flush with the surface of second component. All or some part of exposed dimension-changing first component 1408 is preferentially coated with an adhesive layer 1416 (see also, FIG. 1, coating 124). One or more optional anti-bonding coatings (not shown) may be applied to the second component 1412 (FIG. 1, coating 128), as desired.

Confronting a working face 1420 of the first component 1408 is a microelectronic-device die 1424 having a front surface 1428 and a back surface 1432. As depicted, the front surface 1428 of the microelectronic-device die 1424 is facing the working face 1420 of the differential-movement transfer stamp 1400.

FIG. 14B illustrates an example removably securing process, wherein the front surface 1428 of the microelectronic-device die 1424 is reversibly secured to the front surface 1416A (FIG. 14A) of the adhesive layer 1416 on the dimension-changing first component 1408 of the differential-movement transfer stamp 1400 so as to effectively form an assembly 1436. In this example, this may be accomplished by bringing the microelectronic-device die 1424 proximate to the differential-movement transfer stamp 1400, or vice versa, at the front surface 1416A of the adhesive layer 1416, holding them firmly against each other, and activating the adhesive layer to complete the bond. This bonding only occurs between microelectronic-device die front surface 1428 and the adhesive layer 1416. Bonding of wafers and other bodies with adhesive is well known in art, and these techniques can be used here, including any suitable modifications known in the art. This bonding technique of FIG. 14A and FIG. 14B may be used along with the bonding technique revealed in FIGS. 12A and 12B earlier, if so desired.

### II.G.4 Magnetic Bonding

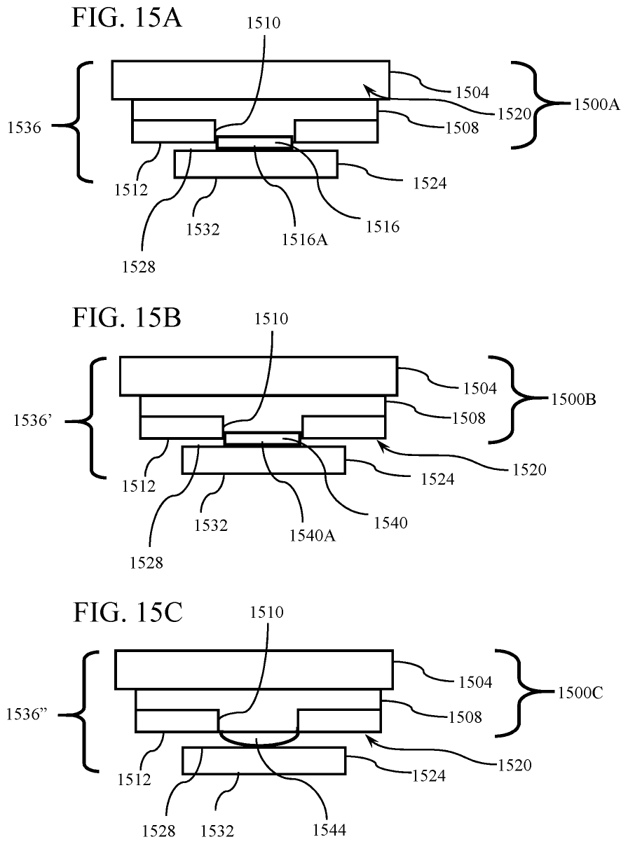

FIGS. 15A-15C illustrate some example alternative methods of utilizing differential-movement transfer stamps 1500A to 1500C of the present disclosure for removably securing a microelectronic-device die 1524 thereto.

FIG. 15A shows differential-movement transfer stamp 1500A that includes a substrate 1504, a dimension-changing first component 1508 on top of the substrate 1504, and non-dimension-changing second component 1512 atop the dimension-changing component 1508. The dimension-changing first component 1508 extends into a compartmentalized cavity 1510 formed in the second component 1512. All or some part of the portion of the dimension-changing first component 1508 exposed on the working face 1520 of the differential-movement transfer stamp 1500A is preferentially coated with a magnetic layer 1516 (see also FIG. 1, coating 124). One or more optional anti-bonding coatings (not shown) may be applied to the second component 1512 (FIG. 1, coating 128). When the microelectronic-device die 1524 is removably secured to the differential-movement transfer stamp 1500A, they form a temporary assembly 1536.

As also depicted in FIG. 15A, if the microelectronic-device die 1524 can be coated with a material, such as a functional material (material that has intrinsic use and purpose in the final device), that is magnetic or paramagnetic, then such a microelectronic-device die could be removably secured on the front surface of the permanent magnetic coating layer 1516 of the differential-movement transfer stamp 1500A via magnetism. Techniques for making the permanent magnetic coating layer 1516 are well known in literature and not elaborated on here.

### II.G.5 Electret Bonding

FIG. 15B is identical to FIG. 15A with the exception that one or more electret coating layers 1540 is/are preferentially coated atop all or some part of the portion of the dimension-changing first component 1508 exposed on the working face 1520 of the differential-movement transfer stamp 1500B. The electret coating layer(s) 1540 may utilize any one or more of the electret materials described herein, among others. As is well known in prior art, charged particles create electric fields. These electric fields each have a magnitude and a direction. The electro-static electric field/force exerted by an electret coating can be used to removably secure the microelectronic-device die 1524 onto the differential-movement transfer stamp 1500B. Techniques for making electret coating layer(s) 1540 are well known in literature and not elaborated on here. When the microelectronic-device die 1524 is removably secured to the differential-movement transfer stamp 1500B, they form a temporary assembly 1536′.

### II.G.6 Capillary-Force Bonding

FIG. 15C is identical to each of FIGS. 15A and 15B with the exceptions that a liquid layer 1544 is preferentially housed atop all or some part of the portion of the dimension-changing first component 1508 exposed on the working surface 1520 of the differential-movement transfer stamp 1500C. Capillary forces exerted by this liquid layer 1544 can be used to removably secure the microelectronic-device die 1524 onto the differential-movement transfer stamp 1500C so as to effectively form an assembly 1536″. The liquid layer 1544 can be organic or inorganic or hybrid in composition. Furthermore, the liquid layer 1544 might also have a gel-like consistency. The process of bringing the differential-movement transfer stamp 1500C and/or the microelectronic-device die 1524 proximate to each other to initiate bonding are not depicted in FIGS. 15A to 15C, as these are known in prior art. The bonding techniques of FIG. 15A-15C may be used along with the bonding technique revealed in FIGS. 12A-12B earlier, if so desired.

### II.H Releasing the Microelectronic-Device Die from the Differential-Movement Transfer Stamp

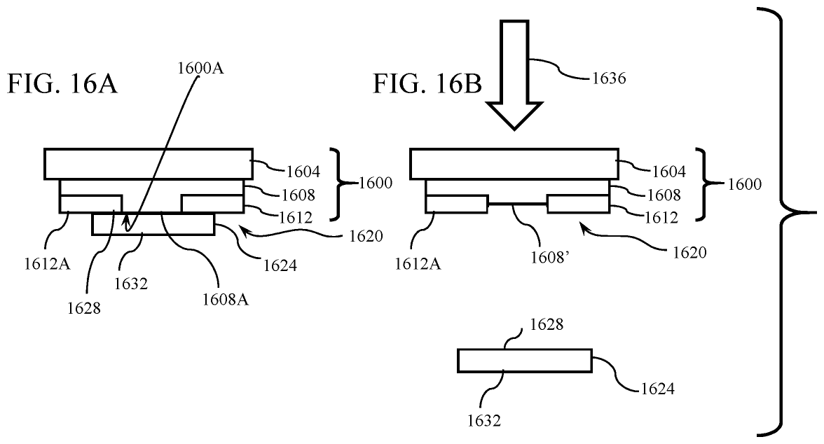

FIGS. 16A-16B through FIGS. 19A-19B illustrate various aspects utilizing a differential-movement transfer stamp 100 (FIG. 1) in releasing a microelectronic-device die releasably secured thereon from the differential-movement transfer stamp. For the ease of illustration, all of these examples are simplified by using the single-second component functional unit 120 illustrated in FIG. 11. However, the aspects and features illustrated in the FIGS. 16A-16B through 19A-19B may be incorporated into any suitable differential-movement transfer stamp disclosed herein.

FIG. 16A illustrates a microelectronic-device die 1624 reversibly secured on the working face 1600A of the differential-movement transfer stamp 1600 to the front surface 1608A of the first component 1608. As described above in connection with FIG. 12B, in this example, bonding or other reversable securement only occurs between the microelectronic-device die front surface 1628 and the first component 1608. In this example, there is no bonding between the front surface 1612A of the second component 1612 and the front surface 1628 of the microelectronic die 1624.

Referring now to FIG. 16B and setting the first component 1608 of FIG. 16A as a dimension-changing component, when activated by a suitable activator 1636, the dimension-changing first component 1608 undergoes dimension-change, physical contraction in this case, to provide a contracted first component 1608′. This physical contraction pulls the reversibly secured microelectronic-device die 1624 against the front surface 1612A of the second component 1612, which in this case is a non-dimension-changing component, and at some point, the bond between the dimension-changing component 1608 and the microelectronic-device die 1624 gives way, causing the differential-movement transfer stamp 1600 to release the microelectronic-device die, as depicted. The front surface 1612A of the second component 1612 effectively acts a mechanical stop to release the reversibly secured microelectronic-device die 1624 from the working face 1620 of the differential-movement transfer stamp 1600. It is assumed that the overall system is designed so that the microelectronic-device die 1624 does not crumple or otherwise deform due to the physical contraction of the dimension-changing first component 1608 and that the bonding interface/strength is low enough for release of the microelectronic-device die 1624 without the microelectronic-device die 1624 substantially structurally failing.

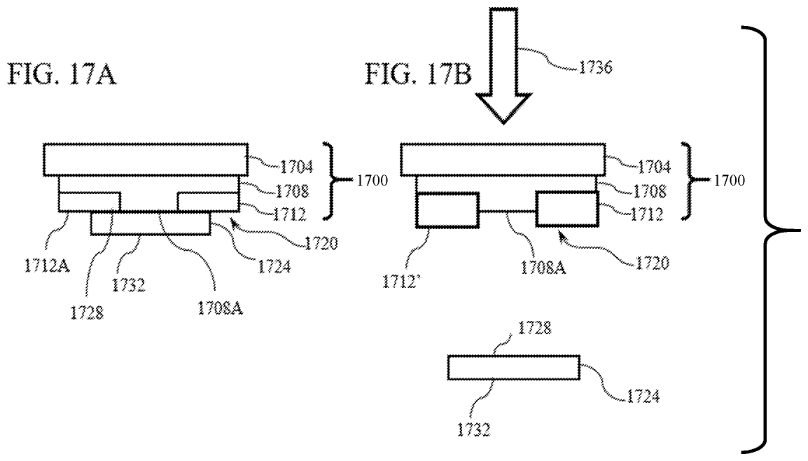

FIG. 17A illustrates a microelectronic-device die 1724 reversibly secured to the front surface 1708A of the first component 1708 of the differential-movement transfer stamp 1700. As described above in connection with FIG. 12B, in this example bonding or other reversable securement only occurs between microelectronic-device die surface 1728 and the front surface 1708A of the first component 1708. There is no bonding between surface 1712A of the second component 1712 and the microelectronic-device die surface 1728.

Referring now to FIG. 17B, and setting the second component 1712 of FIG. 17A as a dimension-changing component, when activated by a suitable activator 1736, dimension-changing second component 1712, undergoes dimension-change, physical expansion in this case, to provide an expanded second component 1712′. This physical expansion forces the bonding interface between the front surface 1708A of the first component 1708, which in this case is a non-dimension-changing component, and microelectronic-device die surface 1728 to give way, resulting in release of the microelectronic-device die at surface 1728, as depicted. Front surface 1712A of the second component 1712 effectively acts a mechanical pusher to release the reversibly secured microelectronic-device die 1724 from the working face 1720 of the differential-movement transfer stamp 1700.

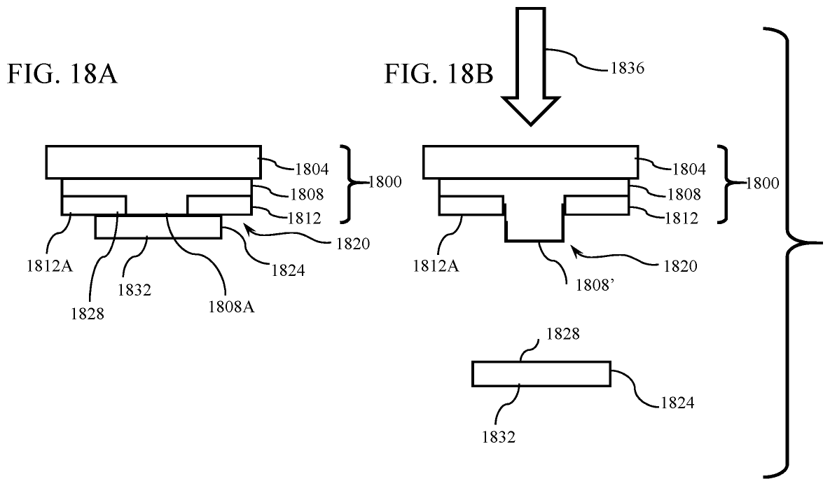

FIG. 18A illustrates a microelectronic-device die 1824 reversibly secured to the front surface 1812A of the second component 1812 of the differential-movement transfer stamp 1800. In this example, bonding or other reversable securement only occurs between microelectronic-device die surface 1828 and the second component 1812. There is no bonding between the front surface 1808A of first component 1808 and the microelectronic-device die surface 1828.

Referring now to FIG. 18B, and setting the first component 1808 of FIG. 18A as a dimension-changing component, when activated by a suitable activator 1836, the dimension-changing first component 1808, undergoes dimension-change, physical expansion in this case, to provide an expanded first component 1808′. This physical expansion forces the bonding interface between the front surface 1812A of the second component 1812, which in this case is a non-dimension-changing component, and the microelectronic-device die surface 1828 to give way, resulting in release of the microelectronic-device die at surface 1828, as depicted. The front surface 1808A of the first component 1808 effectively acts a mechanical pusher to release the reversibly secured microelectronic-device die 1824 from the working face 1820 of the differential-movement transfer stamp 1800.

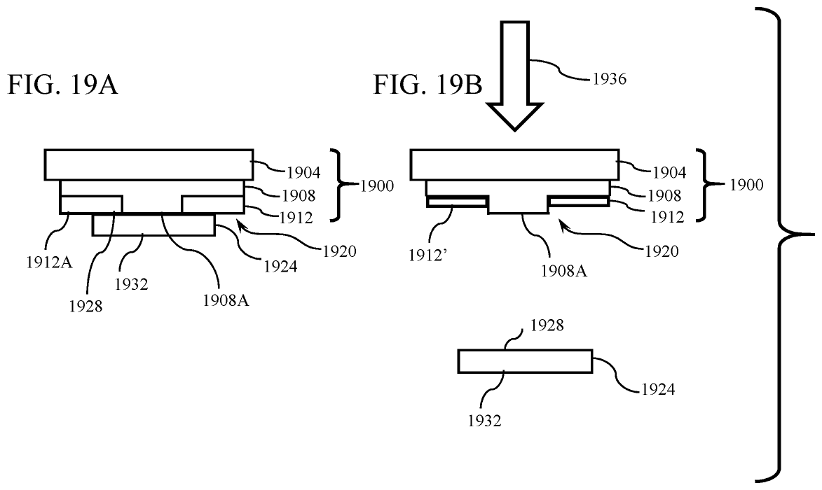

FIG. 19A illustrates a microelectronic-device die 1924 reversibly secured to the front surface 1912A of the second component 1912 of the differential-movement transfer stamp 1900. In this example, bonding or other reversible securement only occurs between microelectronic-device die surface 1928 and the second component 1912. There is no bonding between the front surface 1908A of the first component 1908 and the microelectronic-device die surface 1928.

Referring now to FIG. 19B, and setting the second component 1912 of FIG. 19A as a dimension-changing component, when activated by a suitable activator 1936, the dimension-changing second component 1912, undergoes dimension-change, physical contraction in this case, to a contracted second component 1912′. This physical contraction forces the microelectronic-device die 1924 against the first component 1908, which in this case is a non-dimension-changing component, thereby forcing the bonding interface between the front surface 1912A of the second component 1912 and the microelectronic-device die surface 1928 to give way, resulting in release of the microelectronic-device die at surface 1928, as depicted. The front surface 1908A of the first component 1908 effectively acts a mechanical stop to release the reversibly secured microelectronic-device die 1924 from the working face 1920 of the differential-movement transfer stamp 1900.

As illustrated by the examples of the differential-movement transfer stamp 100 (FIG. 1) depicted in FIGS. 16A-16B through FIGS. 19A-19B, it is apparent that the differential-movement transfer stamp operates by creating a differential-movement between the first and second components of the differential-movement transfer stamp. Furthermore, this relative movement is typically in a direction normal to the working face of the differential-movement transfer stamp.

### II.I Activator(s)

As used herein and in the appended claims, an “activator” is any stimulus that causes each dimension-changing material of either the first component 108 (FIG. 1) or the second component 112, or in some cases both the first and second components, to make the desired dimension change. Examples of such activator, or stimulus, include light or electromagnetic radiation, heat or thermal energy, electrical energy such as voltage and electric current, magnetic field energy, chemistry or chemical energy, or any combination thereof, among others. Electromagnetic radiation may span ultraviolet (UV), visible, near infrared (NIR), mid-wave infrared (MWIR), and far infrared (FIR) wavelengths. There are no limitations on the intensity of the electromagnetic radiation used. The electromagnetic radiation may be uniform or non-uniform in intensity. There are no limitations on the magnitude and duration of the heat or thermal energy used.

The activator may originate external to the differential-movement transfer stamp 100 (FIG. 1) and pass thru the substrate 104. Alternatively or additionally, the activator may originate internal to the differential-movement transfer stamp 100. The activator may be applied globally over the entire differential-movement transfer stamp 100, in which case all of the dimension-changing material responsive to that activator, and corresponding component(s), are activated at the same time. As another example, the activator may be applied locally to some section of the differential-movement transfer stamp 100, such that only the dimension-changing material, and corresponding component(s), in that exposed section are activated. As a further example, the activator might be applied locally to a single functional unit 120 of the differential-movement transfer stamp 100, such that only the dimension-changing material responsive to that activator in that exposed, or activated, functional unit is activated. Fundamentally, there are no limits on the magnitude of the activator/stimulus needed to cause each dimension-changing material to make the desired dimension change, as long as it serves its intended purpose. It is noted that one or more dimension-changing materials may be used with one or more activators, as desired or needed for a particular instantiation.

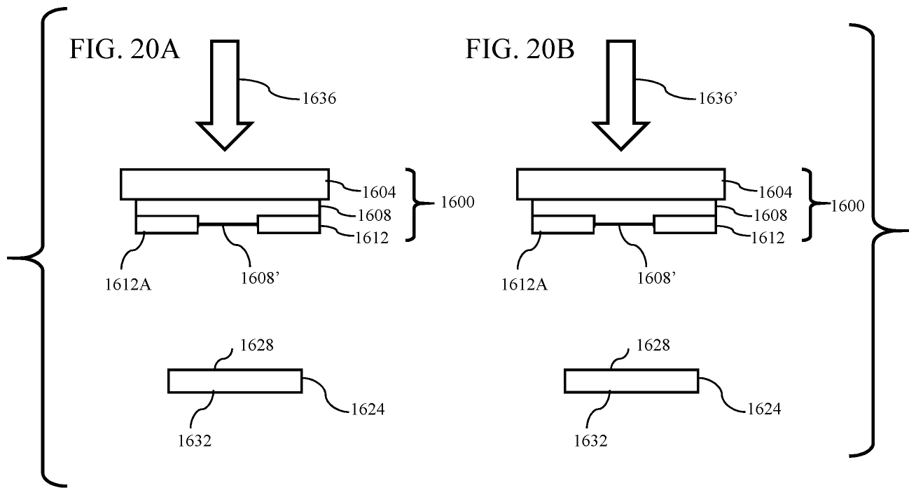

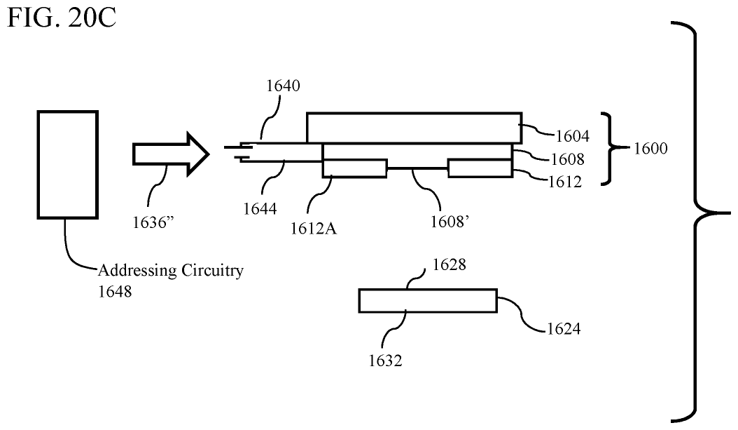

FIG. 20A illustrates a light, or electromagnetic-radiation, based activator 1636. In this example, the activator 1636 is external to the differential-movement transfer stamp 1600 and may come from the top (relative to FIG. 20A) as illustrated in FIG. 20A. In this application, the substrate 1604 would be substantially or entirely transparent to the activator 1636. As another example, the activator 1636 might also or alternatively come from the bottom (relative to FIG. 20A) (not shown), in which case microelectronic-device die 1624 would be substantially or entirely transparent to activator.

FIG. 20B illustrates heat or thermal energy based activator 1636′. In this example, the activator 1636′ is external to the differential-movement transfer stamp 1600 and may come from the top (relative to FIG. 20B), as illustrated in FIG. 20B, or it might come from the bottom (relative to FIG. 20B) (not shown). The activator 1636′ might be applied together in tandem with another process, if so desired. As an example, during the process of affixing a microelectronic-device die 1624 to a final receiving substrate (not shown) using a bonding agent that might need to be thermally liquified to function, the thermal activator 1636′ could be applied to both liquify the bonding agent as well as to activate dimension-changing material of the differential-movement transfer stamp 1600.

FIG. 20C illustrates electricity, for example, voltage, based activator 1636″. In this example, the activator 1636″ is external to differential-movement transfer stamp 1600. Assuming that the dimension-changing material, here in first component 1608, is a dielectric elastomer, compliant electrodes 1640 and 1644 are provided on the first component 1608, as shown. When a voltage is applied at the activator 1636″ across the compliant electrodes 1640 and 1644 to the surfaces of the first component 1608, the dielectric elastomer material undergoes a mechanical contraction by reducing in thickness.

In some embodiments, such as for the depicted activator 1636″ of FIG. 20C, addressing circuitry 1648 can be provided for activating individual ones, or groups of, functional units of the differential-movement transfer stamp structure 1600. Electrical active matrix and passive matrix addressing circuitry is well known in prior art and can be adapted as required for providing addressing circuitry for use in methods of structures of this disclosure.

### II.J Transfer Process Using a Differential-Movement Transfer Stamp

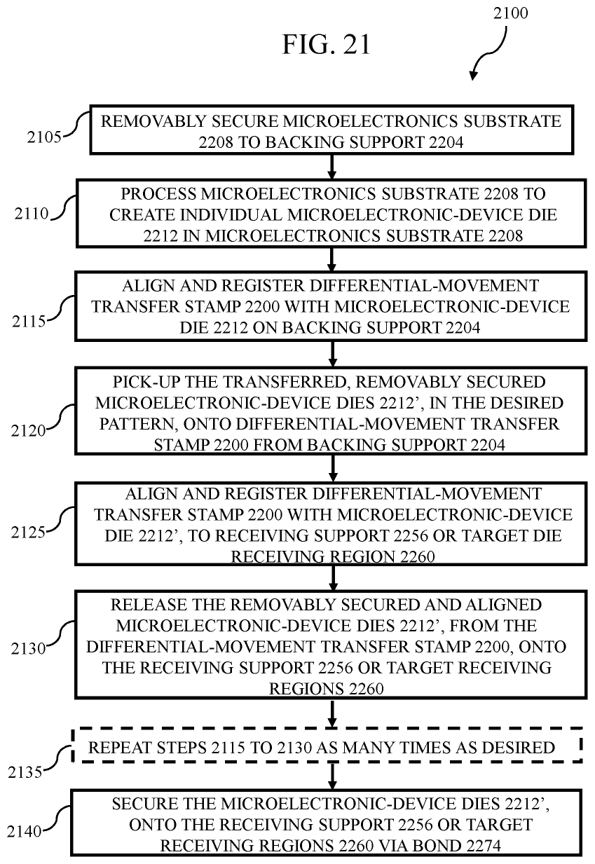

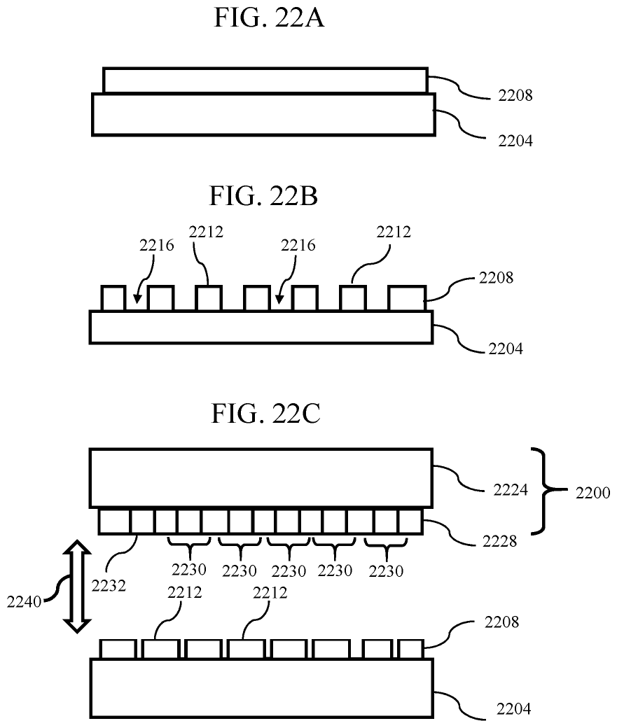

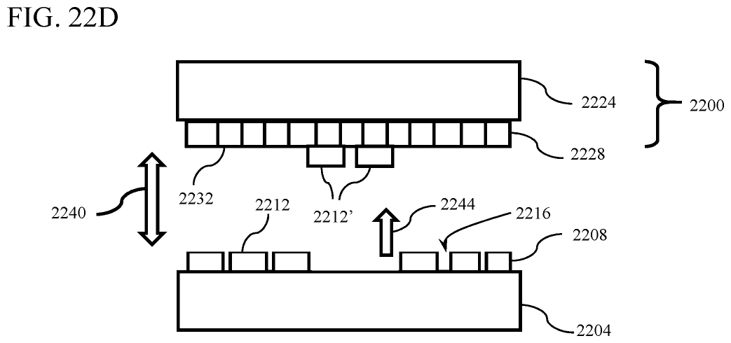

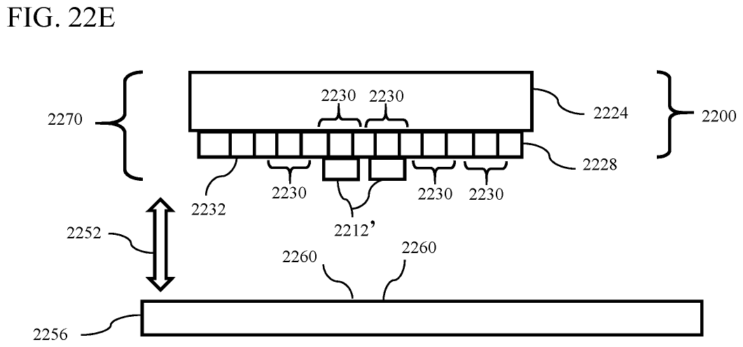

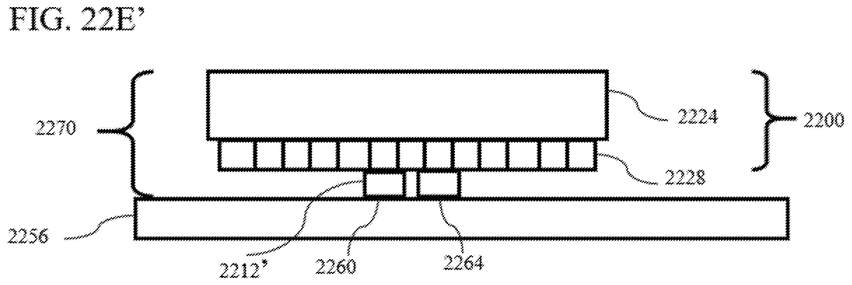

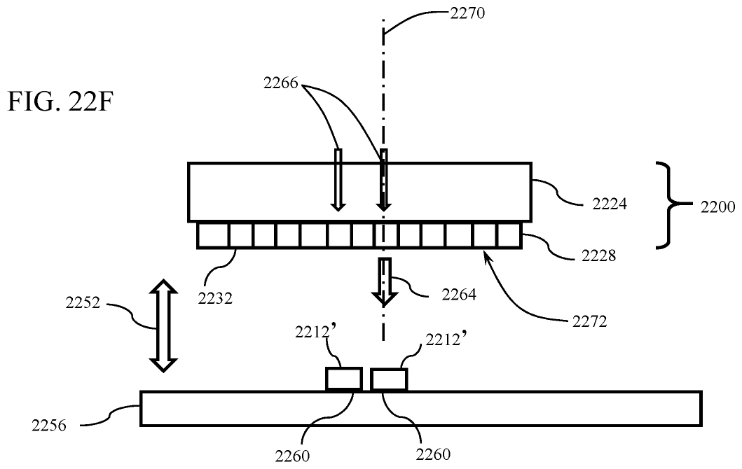

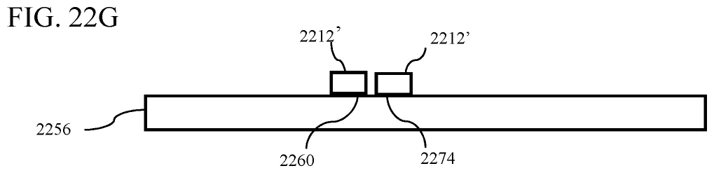

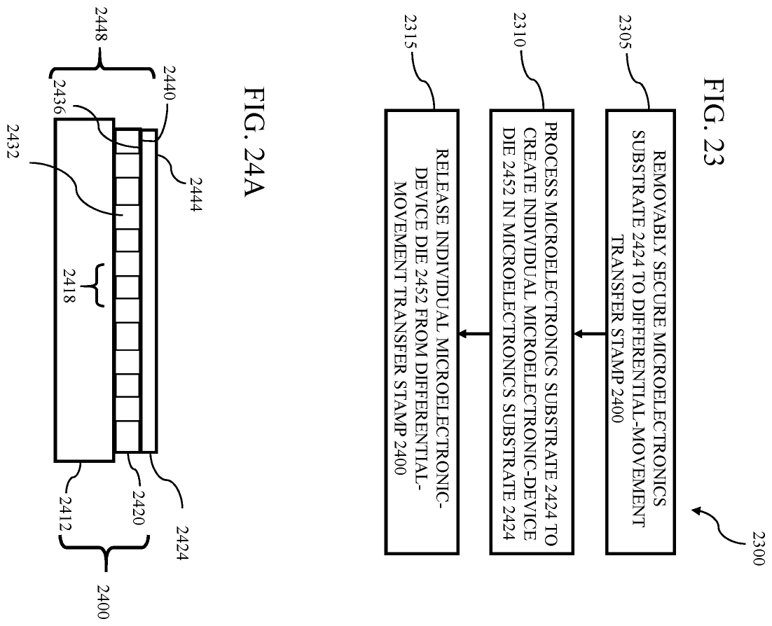

FIGS. 21 and 22A to 22G illustrate an example method 2100 (FIG. 21) of utilizing a differential-movement transfer stamp 2200 (FIG. 22C) for mass transferring individual microelectronic-device dies 2212 created from a microelectronics substrate 2208.

Referring now to FIGS. 22A to 22G, and also to FIG. 21, at block 2105 of the method 2100, the microelectronics substrate 2208 (FIG. 22A) is removably secured to a backing support 2204. Examples of microelectronic-device die and microelectronic device substrate are defined above in section II.G.1.a, and the microelectronics substrate 2208 of FIG. 22A may be as described in that section. Furthermore, the backing support 2204 may comprise of any substrate defined above in section II.A directed to the substrate 104 of FIG. 1. Any of the removably securing techniques revealed above may be used to removably secure the microelectronics substrate 2208 to the backing support 2204.

Alternatively, other bonding techniques may be used, as there are many ways to bond two substrates together. Bonding processes may include microwave bonding, anodic bonding, fusion bonding, adhesive bonding (including glues, silicones, RTV, urethanes, etc.), epoxy bonding, polyimide bonding, BCB (benzocyclobutene) bonding, photo-resist/photo polymer bonding, UV curable materials bonding, metallic bonding, eutectic bonding, solder bonding, indium bonding, thermo-compression bonding, thermo-sonic compression bonding, and/or low temperature glass bonding, glass frit bonding, hybrid bonding (metal+dielectric), plasma enhanced bonding, oxide bonding, DBI (direct bond interconnect), wax bonding, mechanical contact bonding, micro-tube bonding, silicide bonding, laser welding, ultrasonic welding, etc. Bonding may also be initiated by surface treatments using chemicals, activated plasma treatments, vacuum processes etc. These chemicals may be cured/activated using plasma, light, UV, temperature, pressure, anaerobic environment, etc. While certain representative embodiments have been described for purposes of illustrating a point, it will be apparent to those skilled in the art that bonding methods not disclosed herein may be made without departing from the scope of the invention.

At block 2110 of the method 2100 (FIG. 21), the microelectronics substrate 2208 (FIG. 22B) is further processed, in this example by etching 2216, to create individual microelectronic-device dies 2212 from the microelectronics substrate 2208. As may be used herein and/or in the appended claims, the process of forming individual microelectronic-device dies, such as microelectronic-device dies 2212 from a substrate (e.g., wafer), such as microelectronics substrate 2208, can be referred to a “singulation”, “singulating”, and the like.

### II.J.1 Example Processing to Create Individual Microelectronic-device Dies

Still referring to FIGS. 21 and 22A to 22B, the microelectronic substrate 2208 and microelectronic device coating layers (not shown) are partitioned/singulated into individual microelectronic-device dies 2212 by an etching process 2216. Techniques used in conjunctions with the etching process, such as spin coating for a photo-resist, patterning for the photo-resist, exposing the photoresist, and other photolithography processes are well known in prior art and not elaborated upon herein.

Etching techniques to create the individual microelectronic-device dies 2212 may include, but not be limited to, wet chemical etching processes, dry etching processes such as reactive ion etching (RIE), plasma/planar etching, plasma enhanced etching (PE), inductively coupled plasma etching (ICP), deep reactive ion etching (DRIE), sputtering, ion enhanced etching, ion beam milling, chemically assisted ion beam milling, electron cyclotron resonance plasma (ECR), high density plasma (HDP), microwave and RF plasma assisted etching, laser induced/assisted chemical etching, may be individually employed for the same effect. The chemical source may be introduced as flood, time-varying, spatially varying, or continuous. The etching may be performed at low temperature, ambient temperature, or high temperature, and there are fundamentally no temperature constraints on the etching process.

Mechanical techniques to create the individual microelectronic-device dies 2212 might include any of a variety of equipment, such as dicing saws, dicing blades, scribing and break, ablation laser, microjet (with or without liquid), and stealth dicing, among others, may be used. Techniques such as laser ablation, laser photo-ablation, laser induced etching, laser chemical etching, femto-second laser ablation and other ultra-fast laser based etching phenomenon may also or alternatively be used.

While certain representative singulation methods have been described herein for purposes of illustrating aspects of the present disclosure, it will be apparent to those skilled in the art that other etching/removal methods exists and may be used to singulate individual microelectronic-device dies 2212 without departing from the scope of this disclosure.

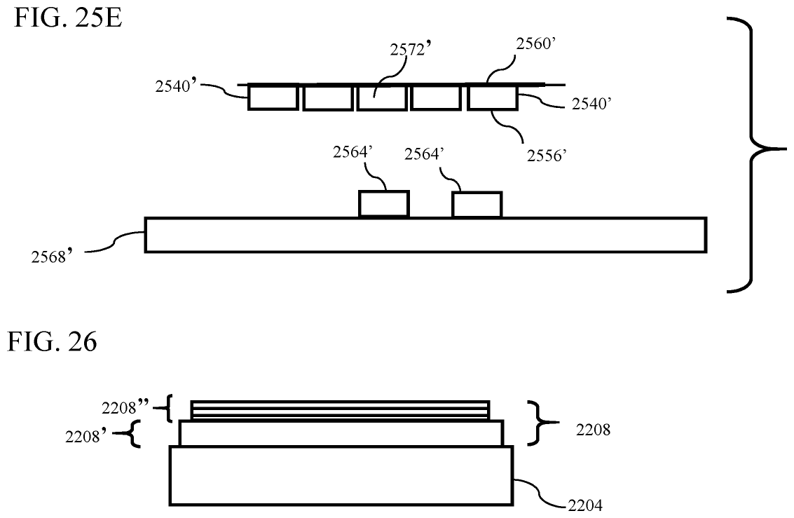

Referring briefly to FIG. 26, the microelectronic substrate 2208 may be considered to comprise a plurality of microelectronics device coating layers 2208″ plus a corresponding portion 2208′ of the microelectronics substrate. Depending on application, it is possible to create the individual microelectronic-device dies 2212 (FIG. 22B) with just the microelectronic device coating layers 2208″ without the underlying portion 2208′ of the microelectronics substrate 2208. It is also possible to create the individual microelectronic-device dies 2212 with the microelectronic device coating layers 2208″ and only part of the underlying portion 2208′ microelectronics substrate 2208. It is further possible to create the individual microelectronic-device dies 2212 with the microelectronic device coating layers 2208″ and all of the underlying portion 2208′ of the microelectronics substrate 2208.

There are no restrictions of the physical size of the individual microelectronic-device dies 2212 created by this process. They may be of any suitable physical size and shape and dimension. Their largest dimension may be, for example, <100 nm, or <1 micron, or <5 microns, or <10 microns, or <20 microns, or <50 microns, or <100 microns, or <1000 microns, or in mm or cm scale.

If a photoresist is used for patterning, this photoresist may be removed if so desired, for example, post processing of the microelectronics substrate 2208 into individual microelectronic-device dies 2212. Removal steps and techniques for photo-resist removal are well known in prior art and not elaborated herein.

In this example and referring again to FIG. 22C, the differential-movement transfer stamp 2200 includes a substrate 2224, a plurality of functional units 2230 each comprising first component 2228 and second component 2232, or portion(s) thereof, with one of the first or second component being composed of a dimension-changing material.

At block 2115 of the method 2100, the differential-movement transfer stamp 2200 (FIG. 22C) is aligned and registered (represented by double arrow-headed line 2240) with the front face of the microelectronic-device dies 2212 removably secured on the backing support 2204. Alignment techniques to align a wafer with a secondary substrate are well known in prior art and not repeated here. These techniques can be used to align the differential-movement transfer stamp 2200 and the microelectronic-device dies 2212 with one another. Alignment techniques using fiduciary marks on some or all relevant wafers/substrates/surfaces, with or without secondary optical elements likes microscopes, objectives etc., are also well known in the semiconductor industry and not detailed here. These techniques can be used, too, in aligning the differential-movement transfer stamp 2200 and the microelectronic-device dies 2212 with one another. Toolsets that allow for relative motion of the wafer and secondary substrate in the x, y, z, and theta axis are well known and not detailed herein, though they too may be used here. Similarly, the use of illumination optics in the visible, UV, NIR, and MWIR spectral regions are well known and can be used here without the need to provide details herein.

At block 2120 of the method 2100, a selected one or more of the removably secured microelectronic-device dies 2212′ are picked up from the backing support 2204 in the desired pattern by first physically engaging the differential-movement transfer stamp 2200 (FIG. 22D) with the front faces of the microelectronic-device dies 2212 removably secured on the backing support 2204. Then, with the selected microelectronic-device dies 2212′ secured thereto, the differential-movement transfer stamp 2200 and/or the backing support 2204 may be moved so as to disengage the selected microelectronic-device dies 2212′ from the backing support.

At block 2125 of the method 2100, now the selected microelectronic-device dies 2212′ removably secured on the differential-movement transfer stamp 2200 (FIG. 22E), are aligned and registered (as represented by double arrow-headed line 2252) with the front surface of a receiving support 2256 and/or specific target die receiving regions 2260.

### II.J.2 Receiving Support

The receiving support 2256 may be a final or intermediate substrate and/or other structure. The receiving support 2256 may be rigid or flexible, or both in differing regions, and may be composed of one or more polymers, ceramics, metals, papers, fabrics, or glasses, or any combination thereof, among other things. The receiving support 2256 may be transparent, opaque, or translucent, or any combination thereof in differing regions. Each material of the receiving support 2256 may be a conductor, an insulator, or a semiconductor. Each material may be inorganic or organic or a combination thereof and may be single crystal, polycrystalline, oriented (or textured) polycrystalline, or amorphous in morphology.

There are fundamentally no limits on the thickness of the receiving support 2256, and in some embodiments the thickness may range from a few microns to several millimeters as desired by application. The surface of the receiving support may be planar (flat), or may be profiled with depressions, cavities, hills, etc.

Additionally or optionally, other functionality and/or one or more functional coatings may be added to and/or deposited in or on the surfaces of the receiving support 2256. The coating(s) may act, for example, as a flex/compliant layer, anti-stick/anti-abrasion layer, barrier layer, passivation layer, planarizing layer, UV protection layer, adhesive layer, color filters, black mask coating, anti-static layer, conductive layer, etc., or any combination thereof. These functional layers include, but are not limited to, organic or inorganic layers.

The receiving support 2256 may include electronic circuitry (not shown) or other electrical functionality pre-built into the receiving support. Examples of such receiving supports include, but are not limited to silicon CMOS back planes, silicon NMOS backplanes, silicon PMOS backplanes, TFTs on glass, PCBs, and FR4, among many others.

It is noted that intermediate substrates are sometimes referred to as “interposers” in literature, and such interposers may be used as a receiving support 2256 of the present disclosure.

While certain representative examples have been mentioned for purposes of illustrating the wide variety of substrates that can be used for the receiving support 2256, it will be apparent to those skilled in the art that substrates not disclosed herein may be made without departing from the scope of the invention.

As show in FIG. 22E and FIG. 22E′, the differential-movement transfer stamp 2200 holding the selected microelectronic-device dies 2212′ may be proximate to, but not touching, or may be spaced a distance, from the receiving support 2256 as illustrated in FIG. 22E. Alternatively, the selected microelectronic-device dies 2212′ removably secured to the differential-movement transfer stamp 2200 may be in intimate contact with receiving support 2256, as illustrated at 2264 in FIG. 22E′.

Referring again to FIG. 22E, in this architecture, once one set of individual microelectronic-device die 2212′ is released, another set of individual microelectronic-device die 2212′ can be dispensed adjacent to and/or in between the first set of individual microelectronic-device die, because the differential-movement transfer stamp 2200 and the selected microelectronic-device dies 2212′ it holds are spaced at a distance from the receiving support 2256.

Referring to FIG. 22E′, in this architecture, once one set (i.e., one or more) of individual microelectronic-device dies 2212′ is released, another set of individual microelectronic-device dies can only be dispensed next to the first set of individual microelectronic-device dies, but not in-between existing individual microelectronic-device die, because the differential-movement transfer stamp 2200 and the selected microelectronic-device dies 2212′ it holds are in intimate contact (or almost intimate contact) with the receiving support 2256.

At block 2130 of the method 2100, one or more of the removably secured microelectronic-device dies 2212′ on the differential-movement transfer stamp 2200 (FIG. 22F) may be released from the differential-movement transfer stamp 2200 onto the front surface of receiving support 2256 or specific target die receiving regions 2260 via a suitable release process (depicted by arrow 2264), for example, as described above in connection with FIGS. 16A-16B through FIGS. 19A-19B.

The release activation 2266 (FIG. 22F) for releasing the individual microelectronic-device die 2212′ from the differential-movement transfer stamp 2200 may be triggered globally releasing all the individual microelectronic-device die 2212′ at one time, or triggered locally releasing one individual microelectronic-device die 2212′ at one time. In this example, the release activation releases the one or more microelectronic-device dies 2212′ in a direction parallel to a release axis 2270 that in this case is normal to the working face 2272 of the differential-movement transfer stamp 2200.

At optional block 2135 of the method 2100, the blocks 2115 through 2130 may be repeated as many times as necessary to populate receiving support 2256 or target die receiving regions 2260, as desired.

At block 2140 of the method 2100 and as illustrated in FIG. 22G, the transferred individual microelectronic-device dies 2212′ are affixed onto the transferred location of the receiving support 2256 or target receiving regions 2260 via a bonding agent 2274.

### II.J.3 Bonding Agent

A bonding agent 2274 may be electrically conductive and comprise one or more metals, silver paste, solders, eutectics, wire meshes, graphite/graphene, CNTs, and/or other electrically conductive formulations. Bonding agent 2274 may be electrically insulating and comprise one or more adhesives, polymers, photo-resist, BCP, glass frits, and/or other electrically insulating formulations. The bonding agent 2274 may allow for temporary bonding or permanent bonding at the location. Optionally, the bonding agent 2274 may utilize vacuum forces, magnetic forces, electro-magnetic forces, static electricity forces (also called “electrets”), electrostatic forces, electrography/xerography (electrical forces) for removably securing the individual microelectronic-device die(s) 2212′.

In some variants, block 2140 of the method 2100 could be implemented prior to the block 2130. Individual microelectronic-device die 2212′ may first be affixed onto the receiving support 2256. The individual microelectronic-device die 2212′ may then be released from the differential-movement transfer stamp 2200 by utilizing a suitable activator 2264 (FIG. 22F). Note that the process blocks of FIG. 22E, FIG. 22E′, FIG. 22F, FIG. 22G can be combined with one another.

Specific advantages of the method 2100 include, but are not necessarily limited to, the following. Mass transfer techniques differ from traditional serial pick and place techniques and typically involve the transfer of many multiple parts (dies, micro-die(s)) simultaneously, also referred to as parallel transfer. These parallel transfer techniques can further transfer parts deterministically (by design and intent), or stochastically (random process). A variety of mass transfer techniques have been developed and/or investigated over the decades. For a multitude of reasons, current mass transfer technologies are not able to provide the speed and precision of transfer required for a variety of industries.

For example, whether in head mounted displays (HMDs) for virtual reality (VR), augmented reality (AR), or mixed reality (MR), near eye displays (NEDs) portend the “next big thing,” ultimately displacing smartphones. For AR to fulfill its enormous potential, the market will demand highly mobile, untethered, discreet and stylish eyewear.

Today's incumbent OLED microdisplays have many shortcomings vis-a-vis AR requirements, in color quality, resolution, brightness, efficiency, and longevity. Inorganic III-V Nitride (GaN/InGaN/AlGaN) based microLEDs (inorganic LED technology) with individually addressable RGB pixels, would be hugely preferred for higher brightness (daylight viewing), high efficiency for long battery life and untethered use and very compact forms, but unfortunately such microLEDs only emit monochrome (blue/violet) light.

To realize high definition, full color, RGB pixels, the respective pixel and sub-pixel sizes for such ILED microdisplays can be on the order of sub 20 microns, or sub 10 microns, or even sub 5 microns. There is currently no mass transfer technology that can allow for the manufacturing of such microdisplays from highly optimized, pre-made, inorganic LED micro dies.

Similarly, there is a need in the solid state lighting market (SSL) to get highly optimized “white” light source and reduce cost of such devices. Having individual R, G, B inorganic LEDs on a singular platform to optimize performance has been a long unmet wish list for the U.S. Department of Energy.

Differential-movement transfer stamps of the present disclosure, such as differential-movement transfer stamp 100 of FIG. 1. and the examples shown throughout the drawings, solve the aforementioned and other issues. Such a differential-movement transfer stamp can be used not only as the base/primary platform for holding/affixing a microelectronics substrate, prior to (and during) etching the microelectronics substrate, into individual microelectronic-device die, but also for the deterministic mass transfer of these etched individual microelectronic-device onto a separate, desired receiving support with a great degree of positional accuracy. Since for deterministic mass transfer it is imperative to first know where the individual microelectronic-device die are with a great degree of accuracy, before these individual microelectronic-device die can be picked up and transferred to the desired location. A differential-movement transfer stamp of the present disclosure can provide a convenient and economical way of doing this.

### II.K. Forming Individual Microelectronic-Device Dies on Differential-Movement Transfer Stamp

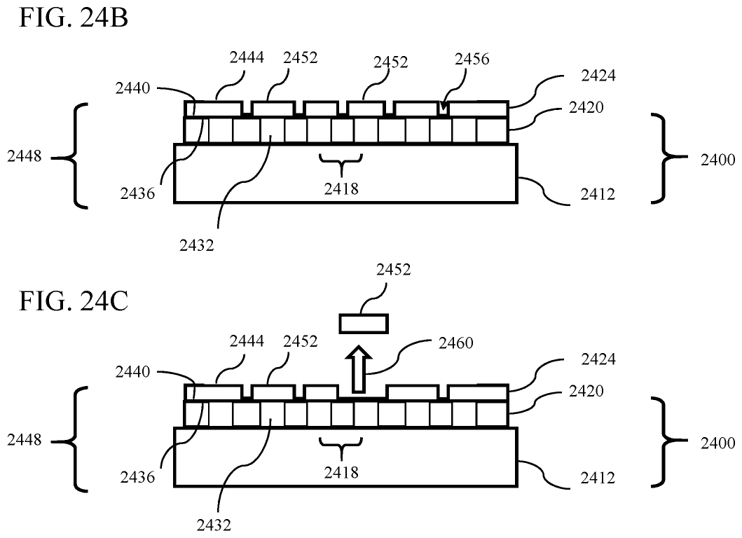

FIGS. 23 and 24A to 24C illustrate an example method 2300 of utilizing an example differential-movement transfer stamp 2400 made in accordance with aspects of the present disclosure to handle a microelectronics substrate 2424 and also to hold the microelectronics substrate during creation of individual microelectronic-device dies 2452.

Referring to FIGS. 24A-24C, and also to FIG. 23, at block 2305 of the method 2300, the microelectronics substrate 2424 (FIG. 24A) is removably secured to the differential-movement transfer stamp 2400. In this example, differential-movement transfer stamp 2400 includes a substrate 2412 and a plurality of functional units 2418 each comprising a first component 2432 and a second component 2420, with one of the first or second component being composed at least partially of a dimension-changing material. Facing the working face 2436 of the differential movement transfer stamp 2400 is a front surface 2440 of the microelectronics substrate 2424. In this example, the microelectronics substrate 2424 may include various microelectronic device coating layers (not shown), which may be located on the front surface 2440 or the back surface 2444, or both the front and back surfaces. There are no implied limitations on orientation of the microelectronic device layers with respect to the surfaces 2440 and 2444 of the microelectronics substrate 2424. As depicted, the front surface 2440 of the microelectronics substrate 2424 is removably secured at the working face 2436 of the differential-movement transfer stamp 2400 so as to form an assembly 2448.

At block 2310 of the method 2300, the microelectronics substrate 2424 (FIG. 24B) may further be processed to singulate the individual microelectronic-device die 2452, in this example by etching 2456, in-situ, in microelectronics substrate 2424. At block 2315 of the method 2300, one or more individual microelectronic-device dies 2452 (FIG. 24C) may be released from the differential-movement transfer stamp 2400 via a suitable release process (depicted by arrow 2460), for example, as described above in connection with FIGS. 16A-16B to FIGS. 19A-19B.

Specific advantages of the method 2300 include the following. In current conventional singulation processes to create individual micro-die(s), the microelectronics device wafer (or substrate) is mounted on a thermal or non-thermal adhesive tape, or a UV tape, which in turn might be mounted onto a porous/non-porous vacuum chuck, or an electro-static chuck. These mounting techniques can be employed for larger individual die(s), for example, die(s) with sizes >100 microns. However, various tapes (adhesive/polymer layers) used in these mounting techniques can suffer from elongation/dimensional instability as they are too compliant/flexible and do not hold the micro-die(s) with the required/desired positional accuracy as might be needed for high finesse work. Additionally, the use of such adhesive tapes also raises the issue of tape residues and contaminants that can adhere to the micro-die(s). In addition, it is well known that removal of singulated die(s) from conventional tapes requires a “peel” or “shear” force, and it is typically not possible to simply “lift” the die(s) vertically.

As should be apparent from descriptions above, such as in section I.A, above, and relative to FIGS. 22A-22G and 24C, the presently revealed release/de-bonding process can allow for vertical release, with no residue on the individual microelectronic-device die(s). Therefore, the differential-movement transfer stamp 2400, or any differential-movement transfer stamp made and used according to the present disclosure, can be used as the base/primary platform for holding/affixing a microelectronics substrate, such as the microelectronics substrate 2424, prior to (and during) singulating the microelectronics substrate into individual microelectronic-device dies. Furthermore, the releasably holding ability of the differential-movement transfer stamp 2400 provides for a monolithic, rigid, passive, self-contained, internal and integrated reversible bonding force, which can be individually addressed and reversed to allow for clean release of micro-die(s).

As other examples, the differential-movement transfer stamp 2400, or any differential-movement transfer stamp made and used according to the present disclosure, can be used as the base/primary platform to reversibly secure wafers, such as silicon wafers, with or without devices layers and then back-thin the wafer, for example to reduce its thickness. This back-thinning could include processes like grinding, polishing, CMP of the wafer, chemical etching, liquid etching, etc. The differential-movement transfer stamp 2400 can be used to reversibly secure thin wafers, such as silicon wafers, with or without devices layers and then create through vias in such thin wafers.

### II.L Differential-Movement Transfer Stamp Having Out-of-Plane Functional Units

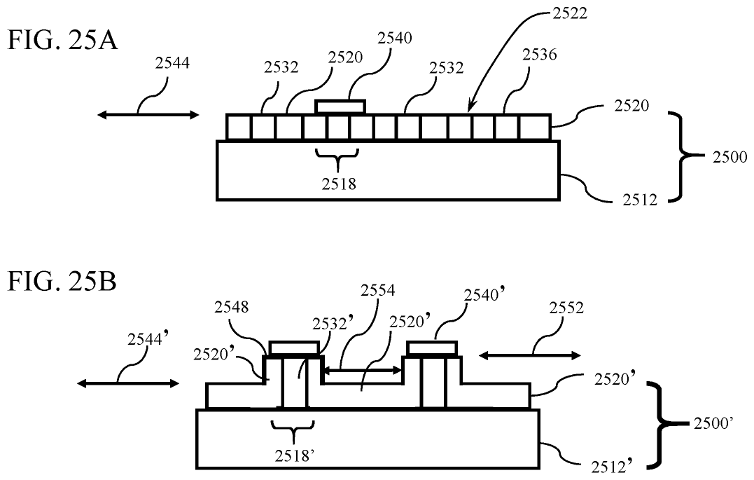

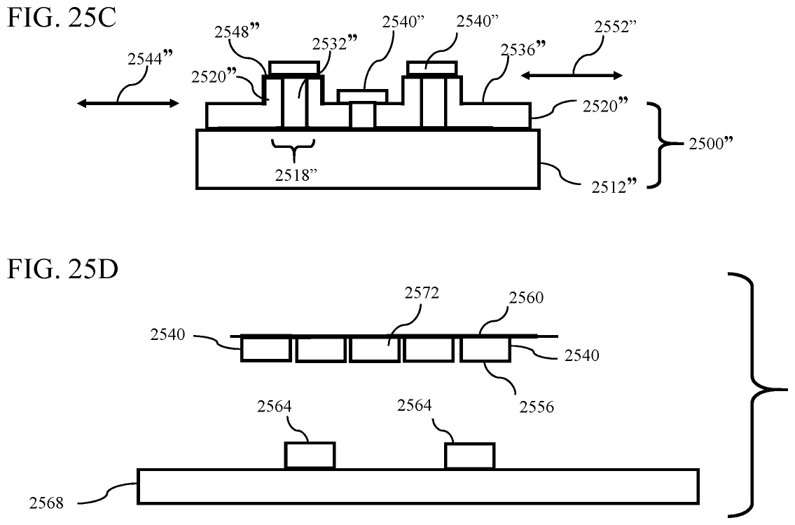

FIGS. 25A to 25E illustrate another example variant of a differential-movement transfer stamp 2500 made in accordance with aspects of the present disclosure. As seen in FIG. 25A, the differential-movement transfer stamp 2500 includes a substrate 2512 and a plurality of functional units 2518 each comprising a first component 2532 and a second component 2520, with one of the first and second components being composed at least partially of a dimension-changing material. In this example, a single microelectronic-device die 2540 is releasable engaged with and atop a corresponding functional unit 2518.

Each of the functional units 2518 may be considered to have a top 2536, i.e., a portion that would engage a corresponding microelectronic-device die or microelectronics substrate when the differential-movement transfer stamp 2500 and the microelectronic-device die or microelectronics substrate are brought into contact with one another. Double-headed arrow 2544 refers to the tops 2536 of the functional units 2518 being substantially in-plane with the working face 2522 of the differential-movement transfer stamp 2500.

FIG. 25B shows a differential-movement transfer stamp 2500′ as including a substrate 2512′ and a plurality of functional units 2518′ each comprising a first component 2532′ and a second component 2520′, with one of the first and second components being composed at least partially of a dimension-changing material. In this example, a pair of microelectronic-device dies 2540′ are engaged with and atop corresponding respective ones of the functional units 2518′.

Each of the functional units 2518′ may be considered to have a top 2548. Double-headed arrow 2552 refers to the tops 2548 of the functional units 2518′, whereas the top surface of surrounding regions of the differential-movement transfer stamp 2500′ is indicated by double-headed arrow 2544′. As can be seen by comparing the vertical locations (relative to FIG. 25B) of the double-headed arrows 2544′ and 2552, the tops 2548 of the functional units 2518′ are substantially out-of-plane with the top surface of the surrounding regions of the differential-movement transfer stamp. In this example, the mean position (represented by double-headed arrow 2554) of the multi-level surface of the differential-movement transfer stamp 2500′ is located vertically (relative to FIG. 25B) between the vertical locations of the tops 2548 of the functional units 2518′ and the top surface of the surrounding regions, as represented by double-headed arrows 2552 and 2544′, respectively.

FIG. 25C shows a differential-movement transfer stamp 2500″ as including a substrate body 2512″ and a plurality of functional units 2518″ each comprising a first component 2532″ and a second component 2520″, with one of the first and second components being composed at least partially of a dimension-changing material. In this example, three microelectronic-device dies 2540″ are engaged with and atop corresponding respective ones of the functional units 2518″.

In this example, some of the functional units 2518″ may be considered to have a top 2548″. Double-headed arrow 2552″ refers to the tops 2548″ of the “out-of-plane” ones 2552″ of the functional units 2518″, whereas some of the functional units may be considered to have a top 2536″. Double-headed arrow 2544″ refers to the tops 2536″ of the “in-plane” ones 2544″ of the functional units 2518″ of the example differential-movement transfer stamp 2500″. The out-of-plane functional units 2552″ and the in-plane functional units 2544″ may be of the same/similar heights or be of different heights. The differential-movement transfer stamp 2500″ may contain both sets of in-plane and out-of-plane function units 2544″ and 2552″, as needed.

FIG. 25D shows a microelectronics-device die 2540 having a front surface 2556 and a back surface 2560. The back surface 2560 is removably secured to a differential-movement transfer stamp (not depicted). Facing the front surface 2556 is a receiving support 2568. Some individual microelectronic-device dies 2564 are already transferred and affixed onto the receiving support 2568.

Out-of-plane functional units, such as the out-of-plane functional units 2518′ and 2552″ of FIGS. 25B and 25C, respectively, allow for the placement of one or more individual microelectronic-device dies 2572 in between existing individual microelectronic-device dies 2564 on the receiving support 2568. This allows for the repair and removal of defective dies and replacement with known good dies, etc. This ability to finely manipulate in-between dies is very crucial for mass transfer techniques.

FIG. 25E shows a microelectronics-device die 2540′ having a front surface 2556′ and a back surface 2560′. The back surface 2560′ is removably secured to a differential-movement transfer stamp (not depicted). Facing the front surface 2556′ is a receiving support 2568′. Some individual microelectronic-device dies 2564′ are already transferred and affixed onto the receiving support 2568′.

Out-of-plane functional units, such as the out-of-plane functional units 2518′ and 2552″ of FIGS. 25B and 25C, respectively, allow for the placement of one or more individual microelectronic-device dies 2572′ adjacent to existing microelectronic-device dies 2564′ on the receiving support 2568′. Therefore, a differential-movement transfer stamp having in-plane functional units could be used to transfer individual microelectronic-device die(s) onto a differential-movement transfer stamp having out-of-plane functional units for further processing.

Example embodiments have been disclosed above and illustrated in the accompanying drawings. It will be understood by those skilled in the art that various changes, omissions, and additions may be made to that which is specifically disclosed herein without departing from the spirit and scope of the present disclosure.

1. A tool for making an electronic device that includes a microelectronics-device die, the tool comprising:
a differential-movement transfer stamp that includes:
a working face designed and configured to removably secure the microelectronic-device die to the differential-movement transfer stamp;
a first component having a first face exposed on the working face and comprising a first material; and
a second component having a second face exposed on the working face and comprising a second material different from the first material;
wherein:
the first and second materials are selected so that, when at least one of the first and second materials is activated by at least one selected activator, the first and second faces experience a differential movement relative to one another in a direction normal to the working face; and
when the microelectronic-device die is removably secured on the working face so as to extend over the first and second faces, the differential movement causes the differential-movement transfer stamp to release the microelectronic-device die.

2. The tool of claim 1, wherein the differential-movement transfer stamp includes a substrate that supports the first and second components of the differential-movement transfer stamp.

3. The tool of claim 2, wherein the at least one selected activator comprises energy, and the substrate is functionally transparent to the energy.

4. The tool of claim 2, wherein the at least one selected activator comprises energy, and the substrate is not functionally transparent to the energy.

5. The tool of claim 2, wherein the substrate comprises the second material and the second component is monolithically formed with the substrate.

6. The tool of claim 1, wherein the first material of the first component comprises a dimension-changing material.

7. The tool of claim 6, wherein the second component does not comprise a dimension-changing material.

8. The tool of claim 6, wherein, during use:
the dimension-changing material reversibly contracts in response to the at least one selected activator so as to cause the differential movement;
the microelectronic-device die is removably secured to the first surface of the first component; and
the second component functions as a stop that causes the microelectronic-device die to release from the first component in response to the differential movement.

9. The tool of claim 8, wherein the dimension-changing material comprises a shape memory polymer.

10. The tool of claim 8, wherein the dimension-changing material comprises a shape memory alloy.

11. The tool of claim 8, wherein the dimension-changing material comprises a liquid-crystal elastomer.

12. The tool of claim 8, wherein the dimension-changing material comprises a dielectric elastomer.

13. The tool of claim 8, wherein the dimension-changing material comprises a ferroelectric elastomer.

14. The tool of claim 8, wherein the at least one selected activator is light.

15. The tool of claim 8, wherein the at least one selected activator is heat.

16. The tool of claim 8, wherein the at least one selected activator is voltage.

17. The tool of claim 8, wherein the at least one selected activator is electric current.

18. The tool of claim 8, wherein the at least one selected activator is a magnetic field.

19. The tool of claim 8, wherein at least one of the first and second materials is activated by a plurality of selected activators.

20. The tool of claim 6, wherein, during use:
the dimension-changing material irreversibly contracts in response to the at least one selected activator so as to cause the differential movement;
the microelectronic-device die is removably secured to the first surface of the first component; and
the second component functions as a stop that causes the microelectronic-device die to release from the first component in response to the differential movement.

21.-308. (canceled)
